(19) United States
(12) Patent Application Publication
(10) Pub. No.: US 2026/0261148 A1
(43) Pub. Date: Sep. 3, 2026

(54) POWERING SYSTEMS AND METHODS FOR SERIES RESONANT CAPACITIVE ELECTRO-QUASI STATIC HUMAN BODY POWERING (EQS-HBP)

(71) Applicant: Quasistatics Inc., West Lafayette, IN (US)

(72) Inventors: Shreyas Sen, West Lafayette, IN (US); Lingke Ding, Lafayette, IN (US); Arunashish Datta, West Lafayette, IN (US)

(21) Appl. No.: 19/066,198

(22) Filed: Feb. 28, 2025

(51) Int. Cl. H02J 50/05; H03H 5/00; H03H 5/12

(52) U.S. Cl. CPC H02J 50/05; H03H 5/003; H03H 5/12

(57) ABSTRACT

Embodiments of the present disclosure disclose a powering system for series resonant capacitive Electro-Quasi Static Human Body Powering (EQS-HBP). The powering system comprises transmitter configured to generate EQS signals for powering receiver and couple the EQS signals to conducting medium. The conducting medium transfers the EQS signals from the transmitter to the receiver. The powering system comprises the receiver electrically attached to conducting medium. The receiver is configured to receive the EQS signals from the transmitter through the conducting medium and deliver power to electrical load. Further, the powering system comprises inductors electrically coupled to one of the transmitter and the receiver. The inductors are configured to boost voltage of the EQS signals coupled to the conducting medium at a series resonant frequency value, based on a quality factor value of the inductors and boost power level of the EQS signals received at the receiver.

### FIELD OF INVENTION

The present disclosure generally relates to the field of powering systems between devices, and more particularly relates to powering systems and methods for series resonant capacitive electro-quasi static human body powering (EQS-HBP).

### BACKGROUND

Generally, at the onset of next technological revolution, human-machine symbiosis has become a central theme across multiple research domains. These domains include development of advanced artificial intelligence (AI) models and integration of AI into wearable devices, enabling improved interaction between humans and machines. In one example, Internet of Bodies (IoB) has been established to address the need for human physiological data collection and seamless human-machine interfacing, providing a low-latency, high-bandwidth, and low-energy network that operates on and around the human body.

Despite the creation of such a network, a fundamental challenge remains in powering on-body devices efficiently and sustainably. Traditionally, these devices rely on battery-powered solutions, which necessitate frequent recharging, sometimes on a daily basis or even multiple times per day. This frequent recharging disrupts continuous usage and becomes increasingly burdensome as the number of on-body devices grows.

Efforts to reduce charging frequency have led to the exploration of low-power communication techniques, such as human-body communication (HBC), which utilizes the conductive properties of the human body to enable energy-efficient data transmission. However, such techniques alone do not eliminate the need for frequent recharging, necessitating the development of convenient energy harvesting techniques and wireless power transfer (WPT) methods to ensure uninterrupted operation.

Traditional energy harvesting and wireless power transfer methods, including piezoelectric, solar, radio frequency (RF), and ultrasound-based techniques, present inherent limitations. These limitations include low energy density, irregular availability, short effective range, and significant attenuation due to human body tissue, restricting their effectiveness in providing reliable and sustained power to on-body devices.

Therefore, there is need for a series resonance capacitive electro-quasistatic (EQS) human body powering (HBP) method when higher power levels are required, to address the aforementioned issues, and more specifically, a more robust, efficient, and higher received power method is needed to enable battery-less on-body devices and address the aforementioned challenges.

### SUMMARY

This summary is provided to introduce a selection of concepts, in a simple manner, which is further described in the detailed description of the disclosure. This summary is neither intended to identify key or essential inventive concepts of the subject matter nor to determine the scope of the disclosure.

An aspect of the present disclosure provides a powering system for series resonant capacitive Electro-Quasi Static Human Body Powering (EQS-HBP) using a Human Body Powering (HBP) network. The powering system comprises a transmitter configured to generate Electro-Quasi static (EQS) signals for powering a receiver. Further, the transmitter is configured to couple the EQS signals to a conducting medium for transmitting the EQS signals, using an Electro-Quasistatic Human Body Powering. The transmitter electrically connects to the conducting medium. The conducting medium transfers the EQS signals from the transmitter to the receiver. The powering system further comprises the receiver electrically attached to the conducting medium. The receiver is configured to receive the EQS signals from the transmitter through the conducting medium, and deliver power to an electrical load associated with the receiver, using the received EQS signals. Further, the powering system comprises one or more inductors electrically coupled to at least one of the transmitter and the receiver. The one or more inductors are configured to boost voltage of the EQS signals coupled to the conducting medium at a series resonant frequency value, based on a quality factor value associated with the one or more inductors and boost power level of the EQS signals received at the receiver.

Another aspect of the present disclosure includes a powering method for series resonant capacitive Electro-Quasi Static Human Body Powering (EQS-HBP) using a Human Body Communication (HBC) network. The powering method includes generating, by a transmitter, Electro-Quasi static (EQS) signals for powering a receiver. Further, the method includes coupling, by the transmitter, the EQS signals to a conducting medium for transmitting the EQS signals, using an Electro-Quasistatic Human Body Powering. The transmitter electrically connects to the conducting medium, and the conducting medium transfers the EQS signals from the transmitter to the receiver. Further, the method includes receiving, by the receiver, the EQS signals from the transmitter through the conducting medium. Further, the method includes delivering, by the receiver, power to an electrical load associated with the receiver, using the received EQS signals. Furthermore, the method includes boosting, by one or more inductors, voltage of the EQS signals coupled to the conducting medium at a series resonant frequency value, based on a quality factor value associated with the one or more inductors. Additionally, the method includes boosting, by the one or more inductors, the power level of the EQS signals received at the receiver.

Yet another aspect of the present disclosure provides a non-transitory computer-readable medium comprising machine-readable instructions that are executable by a processor to perform the method steps as described above.

To further clarify the advantages and features of the present disclosure, a more particular description of the disclosure will follow by reference to specific embodiments thereof, which are illustrated in the appended figures. It is to be appreciated that these figures depict only typical embodiments of the disclosure and are therefore not to be considered limiting in scope. The disclosure will be described and explained with additional specificity and detail with the appended figures.

### BRIEF DESCRIPTION OF DRAWINGS

The disclosure will be described and explained with additional specificity and detail with the accompanying figures in which:

FIGS. 1A-B are example block diagram representations of an exemplary powering system for series resonant capacitive Electro-Quasi Static Human Body Powering (EQS-HBP) using a Human Body Communication (HBC) network, in accordance with an embodiment of the present disclosure;

FIG. 2 is an example block diagram representation of a powering system, such as those shown in FIG. 1, for transferring power to another device using series resonant capacitive Electro-Quasi Static Human Body Powering (EQS-HBP), in accordance with an embodiment of the present disclosure;

FIG. 3 is a schematic representations of a plurality of example ground electrode configurations of transmitter and receiver, in accordance with an embodiment of the present disclosure;

FIGS. 4A-B are circuit diagram representations of an original EQS-HBP lumped circuit with a human body, where the transmitter and the receiver are depicted as ground-floated devices, in accordance with an embodiment of the present disclosure;

FIG. 5A is a circuit diagram representation of series resonance configuration for both transmitter and receiver, in accordance with an embodiment of the present disclosure;

FIG. 5B is a circuit diagram representation of an alternative representation of the transmitter series resonance circuit, emphasizing resonance and the invariance of the V_{body}/V_{Cpp} ratio across frequencies, in accordance with an embodiment of the present disclosure;

FIG. 5C is a circuit diagram representation of optimal placement of an inductor to cancel effect of Cᵣₑₜ through resonance, in accordance with an embodiment of the present disclosure;

FIG. 6A is a graphical representation of voltage ratio Vᵣₓ/V_{body} for a ground-floated RX with series resonance, in accordance with an embodiment of the present disclosure;

FIG. 6B is a graphical representation of three voltage ratios for a ground-floated TX: V_{body}/V_{Cpp}, V_{body}/Vₜₓ, and V_{Cpp}/Vₜₓ, in accordance with an embodiment of the present disclosure;

FIG. 6C is a graphical representation of Zᵢₙ for series, parallel, and no resonance configurations, all with the same RX parasitic capacitances (Cₚₚ=4 pF and Cᵣₑₜ=1 pF), in accordance with an embodiment of the present disclosure;

FIG. 6D is a graphical representation of improvement in Zᵢₙ (Zᵢₙ parallel resonance/Zᵢₙ series resonance) across typical Cₚₚ/Cᵣₑₜ ratios, in accordance with an embodiment of the present disclosure;

FIG. 6E is a graphical representation of Pᵣₓ versus R_{load} for series, parallel, and no resonance configurations under the same conditions as in FIG. 6C, in accordance with an embodiment of the present disclosure;

FIG. 6F is a graphical representation of effect of the inductor Q factor on the Pᵣₓ, where there is a circuit simulation across four configurations of capacitive EQS-HBP where an inductor is used and C_{body}=70 pF, Cᵣₑₜ=1 pF, Cₚₚₜₓ=4 pF, Cₚₚᵣₓ=1 pF, in accordance with an embodiment of the present disclosure;

FIG. 7 is a circuit diagram representation of an inductor with Q factor modelled as R_{ind} for both TX and RX, in accordance with an embodiment of the present disclosure;

FIG. 8 is a graphical representation depicting an effect of transmitter or receiver off-resonance on Pᵣₓ, in accordance with an embodiment of the present disclosure;

FIG. 9A is a graphical representation of an optimal R_{load} that maximizes Pᵣₓ across two scenarios: perfect and imperfect frequency alignment between TX and RX series resonance frequency, in accordance with an embodiment of the present disclosure;

FIG. 9B is a graphical representation of an optimal R_{load} that maximizes Pᵣₓ across different return path impedance, covering from ground-connected RX to ground-floated RX, in accordance with an embodiment of the present disclosure;

FIG. 10A is an experimental setup and comparative results of RX series versus parallel resonance showing that series resonance has higher peak Pᵣₓ than parallel resonance and the impact of varying contact areas, in accordance with an embodiment of the present disclosure;

FIG. 10B is an experimental setup and analysis of TX series versus parallel resonance, highlighting that neither technique will change the ratio of V_{body}/V_{Cpp}, in accordance with an embodiment of the present disclosure; and

FIG. 11 is a process flow diagram depicting an exemplary powering method for series resonant capacitive Electro-Quasi Static Human Body Powering (EQS-HBP) using a Human Body Communication (HBC) network, in accordance with an embodiment of the present disclosure.

Further, those skilled in the art will appreciate that elements in the figures are illustrated for simplicity and may not have necessarily been drawn to scale. Furthermore, in terms of the construction of the device, one or more components of the device may have been represented in the figures by conventional symbols, and the figures may show only those specific details that are pertinent to understanding the embodiments of the present disclosure so as not to obscure the figures with details that will be readily apparent to those skilled in the art having the benefit of the description herein.

### DETAILED DESCRIPTION OF THE DISCLOSURE

For simplicity and illustrative purposes, the present disclosure is described by referring mainly to examples thereof. The examples of the present disclosure described herein may be used together in different combinations. In the following description, details are set forth in order to provide an understanding of the present disclosure. It will be readily apparent, however, that the present disclosure may be practiced without limitation to all these details. Also, throughout the present disclosure, the terms “a” and “an” are intended to denote at least one of a particular element. The terms “a” and “an” may also denote more than one of a particular element. As used herein, the term “includes” means includes but not limited to, the term “including” means including but not limited to. The term “based on” means based at least in part on, the term “based upon” means based at least in part upon, and the term “such as” means such as but not limited to. The term “relevant” means closely connected or appropriate to what is being performed or considered.

For the purpose of promoting an understanding of the principles of the disclosure, reference will now be made to the embodiment illustrated in the figures and specific language will be used to describe them. It will nevertheless be understood that no limitation of the scope of the disclosure is thereby intended. Such alterations and further modifications in the illustrated system, and such further applications of the principles of the disclosure as would normally occur to those skilled in the art are to be construed as being within the scope of the present disclosure. It will be understood by those skilled in the art that the foregoing general description and the following detailed description are exemplary and explanatory of the disclosure and are not intended to be restrictive thereof.

In the present document, the word “exemplary” is used herein to mean “serving as an example, instance, or illustration”. Any embodiment or implementation of the present subject matter described herein as “exemplary” is not necessarily to be construed as preferred or advantageous over other embodiments. The terms “comprise”, “comprising”, or any other variations thereof, are intended to cover a non-exclusive inclusion, such that one or more devices or sub-systems or elements or structures or components preceded by “comprises . . . a” does not, without more constraints, preclude the existence of other devices, sub-systems, additional sub-modules. Appearances of the phrase “in an embodiment”, “in another embodiment”, “in an exemplary embodiment” and similar language throughout this specification may, but not necessarily do, all refer to the same embodiment.

Unless otherwise defined, all technical and scientific terms used herein have the same meaning as commonly understood by those skilled in the art to which this disclosure belongs. The system, methods, and examples provided herein are only illustrative and not intended to be limiting. A computer system (standalone, client, or server, or computer-implemented system) configured by an application may constitute a “module” (or “subsystem”) that is configured and operated to perform certain operations. In one embodiment, the “module” or “subsystem” may be implemented mechanically or electronically, so a module includes dedicated circuitry or logic that is permanently configured (within a special-purpose processor) to perform certain operations. In another embodiment, a “module” or a “subsystem” may also comprise programmable logic or circuitry (as encompassed within a general-purpose processor or other programmable processor) that is temporarily configured by software to perform certain operations. Accordingly, the term “module” or “subsystem” should be understood to encompass a tangible entity, be that an entity that is physically constructed permanently configured (hardwired), or temporarily configured (programmed) to operate in a certain manner and/or to perform certain operations described herein.

Embodiments of the present disclosure provides a wireless power transfer system and method for on-body devices, specifically utilizing capacitive electro-quasistatic (EQS) human body powering (HBP) in the frequency range below, for example, but not limited to, 30 MHz. The system features a transmitter that couples the powering signal to the human body. The system further features a receiver that capacitively senses the on-body powering signal and utilizes the differential voltage across its signal and ground electrodes to drive an electrical load without supplementary energy sources. Further, the system features a series resonant technique to overcome challenges posed by return path capacitance (Cret), significantly enhancing power transfer efficiency. Additionally, the system uses effect of inductor quality factor on power received and discloses a method on approximating the optimal loading impedance after implementing series resonance across different application scenarios.

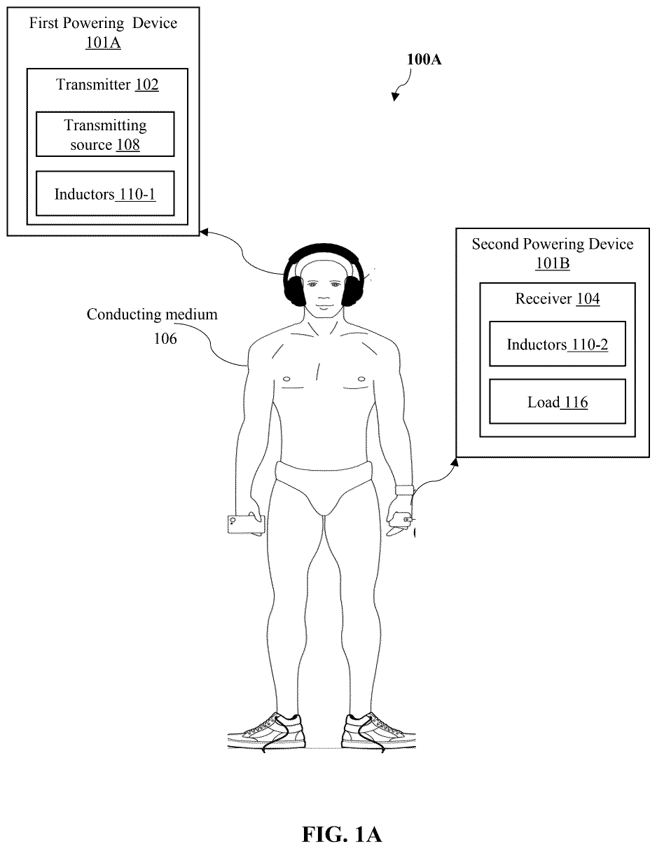

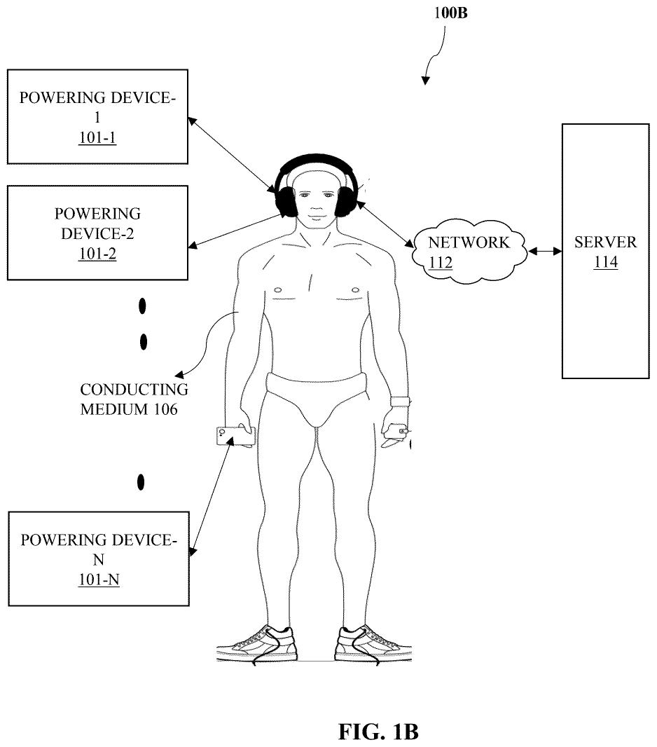

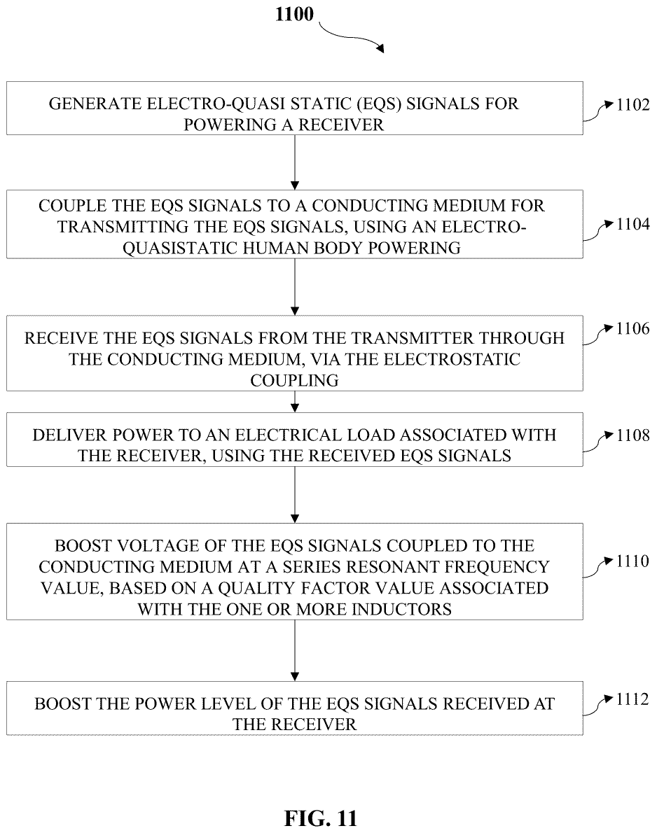

Referring now to the drawings, and more particularly to FIGS. 1A-B through FIG. 11, where similar reference characters denote corresponding features consistently throughout the figures, there are shown preferred embodiments and these embodiments are described in the context of the following exemplary system and/or method.

FIGS. 1A-B are example block diagram representations of an exemplary powering system 100A, 100B for series resonant capacitive Electro-Quasi Static Human Body Powering (EQS-HBP) using a Human Body Communication (HBC) network, in accordance with an embodiment of the present disclosure. The powering system 100A, 100B may include a first powering device 101 A. The first powering device 101 A may include a transmitter 102 (also referred herein as Tx 102). The transmitter 102 may further include a transmitting source 108 and one or more inductors 110-1.

In an embodiment, the powering system 100A, 100B may further include a conducting medium 106 communicatively coupled to the first powering device 101A via a body communication network. In one example embodiment, the conducting medium 106 (also referred herein as human body 106 or body 106 or body channel 106) may be a human body communication network. Further, the conducting medium 106 is configured to establish a powering channel between the first powering device 101A and a second powering device 101B.

In an embodiment, the powering system 100A, 100B may further include the second powering device 101B communicatively coupled to the first powering device 101A via the conducting medium 106. The second powering device 101B may include a receiver 104 (also referred herein as Rx 104). The receiver 104 may include one or more inductors 110-2 and an electrical load 116.

The first powering device 101A and the second powering device 101B may be, for example, but not limited to, a headphone, a smart-watch, a wrist-band, a smart eyewear, any other wearable devices, holdable devices, touchable devices and the like. For example, the price tag display in the supermarket. The conducing medium 106 may be, but not limited to, the human body, a cross-cylindrical human body model, parallel plates and the like.

The transmitter 102 may be, for example, but not limited to, a unit or a subsystem in a watch-based device or a pendant based device or the like. Similarly, the receiver 104 may be, for example, but not limited to, a unit or a subsystem in a sensor device such as a ECG patch, glucose sensor patch or a headphone or the like.

The transmitting source 108 may be for example, but not limited to, a signal generators or the like.

The one or more inductors 110-1 and 110-2 (collectively referred herein as inductors 110) are used in either the transmitter 102 or the receiver 104 or both.

The transmitter 102 generates, couples, and adjusts the electro-quasistatic signal, which may be a periodic signal in the form of either a square wave or a sine wave. The transmitter 102 employs various methods, such as direct current to alternating current conversion, to generate this electro-quasistatic signal. The transmitter 102 has two accessible external nodes: the ground electrode and the signal electrode. To enable power transfer, the transmitter signal electrode must be in contact with or in very close proximity, less than half a centimetre, to the human body 106. The electrode may exist in various forms and sizes, ranging from a bare jumper wire to a large metallic surface.

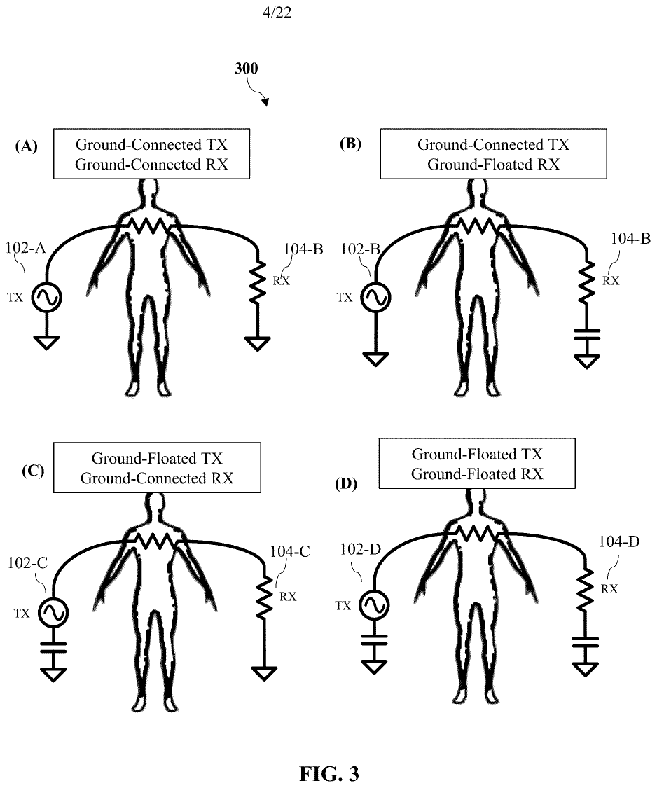

The ground electrode of the transmitter 102 has two distinct configurations. In the first configuration, the transmitter ground electrode is electrically connected to the environmental ground. This connection may be direct, such as a wire connected to a wall-mounted electrical outlet ground, or indirect, such as a metallic plate placed on a large object like a table, acting as a pseudo-ground. In the second configuration, the transmitter ground electrode is not connected to the environmental ground. In this case, the transmitter typically has a mobile power source, such as a battery, and is lifted in the air with its ground electrode not in contact with any objects, including the human body. These ground configurations are shown in detailed in FIG. 3.

The receiver 104 is designed to receive power from the transmitter 102 through the body channel 106 capacitively. Like the transmitter 102, the receiver 104 consists of a signal electrode and a ground electrode. To enable power reception, the receiver signal electrode must be in contact with or in very close proximity, less than half a centimetre, to the human body 106. The receiver ground electrode has two configurations. In the first configuration, the receiver ground electrode is connected to the environmental ground, either directly or through a pseudo-ground. In the second configuration, the receiver ground electrode is not in physical contact with any objects, including the human body 106.

When the transmitter 102 transmits an electro-quasistatic signal through the body channel 106, a differential alternating current voltage is induced across the receiver signal and ground electrodes. This voltage is of the same electro-quasistatic frequency as the transmitter signal but reduced in amplitude. The amount of amplitude reduction depends on the transmitter and receiver ground configurations.

A key aspect of the present disclosure is the incorporation of a series resonance technique to overcome inefficiencies caused by return path capacitance (Cret). In traditional capacitive EQS-HBP systems, Cᵣₑₜ introduces high AC impedance, which limits the power received by the load. By introducing an inductor 110 in series with the load 116, the series resonance cancels the effect of Cret, reducing AC impedance and significantly boosting the received voltage and power. This enhancement improves the RX's 104 capability to sense on-body voltage effectively. On the TX side, by introducing an inductor 110-1 in series with the transmitting source 108 may significantly boost the voltage coupled to the body 106.

In one example embodiment, the transmitter 102 configured to generate Electro-Quasi static (EQS) signals for powering the receiver 104. The transmitter 102 is further configured to couple the EQS signals to a conducting medium 106 for transmitting the EQS signals, using an Electro-Quasistatic Human Body Powering. The transmitter 102 electrically connects to the conducting medium 106 and the conducting medium 106 transfers the EQS signals from the transmitter 102 to the receiver 104.

In one example embodiment, the receiver 104 is electrically attached to the conducting medium 106. The receiver 104 is configured to receive the EQS signals from the transmitter 102 through the conducting medium 106. Further, the receiver 104 is configured to deliver power to an electrical load 116 associated with the receiver 104, using the received EQS signals.

In one example embodiment, the one or more inductors 110 are electrically coupled to either the transmitter 102 or the receiver 104 or both. The one or more inductors 110 are configured to boost voltage of the EQS signals coupled to the conducting medium 106 at a series resonant frequency value, based on a quality factor value associated with the one or more inductors 110. The one or more inductors 110 are further configured to boost power level of the EQS signals received at the receiver 104.

In one example embodiment, to deliver the power to the electrical load 116 associated with the receiver 104, using the received EQS signals, the receiver 104 comprises a signal electrode electrically connected to the conducting medium 106 (also referred herein as conducting medium 106). The signal electrode is configured to receive the EQS signals from the transmitter 102, through the medium 106, where the received EQS signals corresponds to a primary voltage value induced by the EQS signals transmitted from the transmitter 102. Further, the receiver 104 comprises a ground electrode coupled to a ground terminal. The ground electrode is configured to receive a secondary voltage value induced by the EQS signals transmitted from the transmitter 102. The receiver 104 is configured to receive a differential voltage value between the signal electrode, and the ground electrode of the receiver 104, based on the primary voltage value and the secondary voltage value. The receiver 104 is further configured to deliver power to the electrical load 116 associated with the receiver 104, based on the received differential voltage value.

In an example embodiment, the receiver 104 is configured to receive a differential alternating current voltage across the received EQS signal and the ground electrode. The differential alternating current voltage corresponds to a frequency of the electro-quasistatic signals with a reduced amplitude. The amplitude is reduced based on the transmitter 102 and receiver 104 ground configurations.

Further, in an example embodiment, the series resonant frequency value of the transmitter 102 depends on size of the one or more inductors 110 with respect to size of a primary parasitic capacitor connected parallelly to the transmitter 102.

Further, in an example embodiment, to boost the voltage of the EQS signals coupled to the conducting medium 106 at the series resonant frequency value, based on the quality factor value associated with the one or more inductors 110, the one or more inductors 110 are configured to boost the voltage of the EQS signals coupled to the conducting medium 106 with a pre-defined gain. The pre-defined gain is determined by a combination of the quality factor value of the one or more inductors 110 connected in series to the transmitter 102 and an additional resistor value added to adjust an overall gain of a circuit connected in series to the one or more inductors 110.

Further, in an embodiment, the transmitter 102 is coupled to a ground terminal with a primary capacitive coupling. The primary capacitive coupling corresponds to a primary return path parasitic capacitor connected between a ground electrode of the transmitter 102, and the ground terminal.

The receiver 104 is coupled to a ground terminal with a secondary capacitive coupling. The secondary capacitive coupling corresponds to a secondary return path parasitic capacitor connected between a ground electrode of the receiver 104 and the ground terminal.

In an example embodiment, the transmitter 102 is configured to transfer the EQS signals at a frequency of less than 30 MHz.

Furthermore, the one or more additional inductors connected parallelly to a primary parasitic capacitor parallelly connected to the transmitter 102. The one or more additional inductors are configured to optimize an amount of current drawn from the transmitter 102.

The series resonant frequency value of the transmitter 102 is configured to be aligned with the series resonant frequency value of the receiver 104 to boost the power level of the EQS signals received at the receiver 104.

To boost power level of the EQS signals received, the receiver 104, in the ground-floated configuration, comprises an inductor 110 in series with the electrical load 116. Further, the receiver 104 comprises a series resonance between the inductor 110 and at least one capacitor. The at least one capacitor comprises one of a parasitic capacitor Cpp existing between the signal electrode and the ground electrode of the receiver 104, a return path parasitic capacitor (Cret); and one or more additional capacitor in parallel with the parasitic capacitor Cpp to adjust the resonant frequency. The series resonance boosts a voltage received by the electrical load 116 and the series resonance boosts the voltage received through cancellation of effect of the return path parasitic capacitor Cret.

In an example embodiment, the transmitter 102 in the ground floated configuration, comprises an inductor 110 in series with a transmitting source 108. The transmitter 102 further comprises a series resonance between the inductor 110 and at least one capacitor. The at least one capacitor comprises one of a parasitic capacitor Cpp existing between the signal electrode and the ground electrode of the transmitter 102, and an additional capacitor in parallel with the parasitic capacitor Cpp. Further, the series resonance boosts the voltage coupled onto the conducting medium 106 to boost the power transmitted.

At the receiver 104, when the receiver 104 is in ground-floated configuration, with inductor series resonance, the power received depends on a ratio of parasitic capacitor Cpp to return path parasitic capacitor Cret value, and on a specific magnitude value of the return path parasitic capacitor Cret.

At the series resonant transmitter 102 and the series resonant receiver 104, when the transmitter 102 and the receiver 104 are in ground-floated configuration, the power delivered to the load 116 depends on a resonance alignment where a transmitter frequency aligns with a transmitter TX series resonance frequency and where the transmitter TX frequency aligns with a receiver RX series resonance frequency.

At the transmitter 102, when the transmitter 102 is in ground-floated configuration, the power transmitted depends on a parallel resonance, where an inductor 110 is connected in parallel with the transmitter signal source 108, wherein the inductor 110 resonates with the Cpp to induce parallel resonance.

In an example embodiment, the receiver 104 is configured to determine if the receiver 104 is ground connected to determine if a series resonance is required. Further, the receiver 104 is configured to match the impendence to the body impedance and contact impedance if the receiver 104 is ground connected.

In an example embodiment, the receiver 104 is configured to determine if the receiver 104 is ground floated and the series resonance is required. Further, the receiver 104 is configured to determine if the Q factor corresponds to one of a primary value and a secondary value if the receiver 104 is ground-floated and the series resonance is determined to be required. Furthermore, the receiver 104 is configured to determine if an impedance is required to be matched to the receiver when the Q factor corresponds to the secondary value. Also, the receiver 104 is configured to determine if a TX transmitting frequency is aligned with the TX series resonance frequency and aligned with the RX resonance frequency. Furthermore, the receiver 104 is configured to determine the optimal loading resistance based on interactions between reactive components of the inductor and capacitive elements of the capacitors.

In an example embodiment, to determine the optimal loading resistance, the powering system 100 is configured to set the optimal loading resistance value based on the body resistance and the contact impedance if the TX transmitting frequency is aligned with the TX series resonance frequency and aligned with the RX resonance frequency and the inductor quality factor is high. In an example embodiment, low Q refers to Q value<10 and a high Q refers to Q value>100. In between values are generally be considered as low Q but is dependent on the ratio of Cᵣₑₜ and Cₚₚ. If the ratio of Cᵣₑₜ/Cₚₚ is high, then they could be considered as high Q, if it is low, then they would need to be considered as low Q. Further, the powering system 100 is configured to set the optimal loading resistance value based on an Equivalent Series Resistance (ESR) if the TX transmitting frequency is aligned with the TX series resonance frequency and aligned with the RX resonance frequency and the inductor quality factor is low. Furthermore, the powering system 100 is configured to set the optimal loading resistance value based on a residual capacitive reactance if the TX transmitting frequency fails to align with the TX series resonance frequency and with the RX resonance frequency and the inductor quality factor is high. The powering system 100 is configured to set the optimal loading resistance value based on the Equivalent Series Resistance (ESR) of the inductor if the TX transmitting frequency fails to align with the TX series resonance frequency and with the RX resonance frequency and the inductor quality factor is low.

At the ground-floated receiver 104, the one or more inductors 110 are configured to be connected in series with the load 116 to boost the power level of the EQS signals received at the receiver 104.

At the transmitter 102, the one or more inductors 110 are configured to be connected in series with a transmitting source 108 to boost the voltage of the EQS signals coupled to the conducting medium 106. To boost the voltage of the EQS signals, the transmitter 102 is configured to determine if the transmitter 102 is one of ground-connected and ground-floated. Further, the transmitter 102 is configured to determine if series resonance is required to be used and determine a gain value to be used. Furthermore, the transmitter 102 is configured to set the gain value to a lower range if the transmitter 102 is ground-connected and the series resonance us required to be used. Additionally, the transmitter 102 is configured to boost the voltage transmitted if the transmitter 102 is ground-floated, using the series resonance.

In an example embodiment, the powering system 200 comprises a primary parasitic capacitor Cpp connected between a signal electrode, and a ground electrode of the transmitter 102. The powering system 200 further comprises a primary return path parasitic capacitor connected between the ground electrode of the transmitter 102, and a ground terminal. The series resonant frequency value of the transmitter 102 is configured to exist between the one or more inductors, and at least one of the primary parasitic capacitor, and the primary return path parasitic capacitor. The series resonant frequency value of the transmitter 102 boosts the voltage of the EQS signals coupled to the conducting medium 106.

In an example embodiment, the powering system 200 comprises a secondary parasitic capacitor connected between a signal electrode, and a ground electrode of the receiver 104. Further, the powering system 200 comprises the secondary return path parasitic capacitor connected between the ground electrode of the receiver 104, and a ground terminal. The series resonant frequency value of the receiver 104 is configured to exist between the one or more inductors 110, and at least one of the secondary parasitic capacitor, and the secondary return path parasitic capacitor. The series resonant frequency value of the receiver 104 adjusts the impedance value of the secondary return path capacitor, to boost the power level of the EQS signals received at the receiver 104. The quality factor value of the one or more inductors 110 is directly proportional to amount of the power delivered to the receiver 104.

At the transmitter 102, the boosted voltage of the EQS signals coupled to the conducting medium 106 depends on one or more secondary inductors connected in parallel with the transmitter 102. The one or more secondary inductors are configured to operate at a parallel resonant frequency value. The parallel resonant frequency value adjusts the current value through the primary parasitic capacitor, and the series resonant frequency value and the parallel resonant frequency value is configured to align to boost the voltage of the EQS signals coupled to the conducting medium 106.

Those of ordinary skilled in the art will appreciate that the hardware depicted in FIG. 1 may vary for particular implementations. For example, the powering device 101A and 101B may include, such as for example, but not limited to, smart-watch, smart wristband, smart eye-wear, earbuds, headphones, waist-band and the like. The depicted example is provided for the purpose of explanation only and is not meant to imply architectural limitations with respect to the present disclosure.

FIG. 1B illustrates a block diagram representation of an exemplary powering system 100B for series resonant capacitive Electro-Quasi Static Human Body Powering (EQS-HBP) using a Human Body Communication (HBC) network. The powering system 100B includes multiple powering devices 101-1, . . . , 101-N configured to power each other devices via a conducting medium 106. The multiple powering devices 101-1, . . . , 101-N may be similar to the first powering device 101A and the second powering device 101B as shown in FIG. 1A. The multiple powering devices 101-1, . . . , 101-N may include a transmitter 102, and a receiver 104 coupled to the conducting medium 106 via Human Body Communication (HBC). In some example embodiments, each of the multiple powering devices 101-1, . . . , 101-N comprises transceivers for enabling bi-directional power between the multiple powering devices 101-1, . . . , 101-N.

Furthermore, the conducting medium 106 is coupled to an external network 112. The external network 112 may include, but not limited to, Wireless Personal Area Network (WPLAN), Wireless Local Area Network (W LAN), Wireless Metropolitan Area Network, Wireless Wide Area Network and the like. The network 112 may be configured to work as the infrastructure that allows multiple powering devices 101-1, . . . , 101-N to connect, exchange information and transfer power with a server 114. The network 112 establishes a connection between multiple powering devices 101-1, . . . , 101-N, and the server 114, enabling the powering devices 101-1, . . . , 101-N to communicate regardless of their physical location. The server 114 may be configured to function as an intermediary, facilitating the seamless flow of data or power signals between the multiple powering devices 101-1, . . . , 101-N. Further, the server 114 may include a processor (not shown) and a memory (not shown) coupled to the processor (not shown). The memory (not shown) includes processor (not shown)-executable instructions, which on execution, cause the processor (not shown) to perform one or more actions, such as power transfer, data processing, data acquisition, data analysis, power distribution and the like.

Although, FIG. 1B illustrates the powering system 100 communicatively coupled to the server 114 via network 112, one skilled in the art may envision that the powering system 100 may be connected to networks 112 such as, but not limited to, Wireless Personal Area Network (WPLAN), Wireless Local Area Network (W LAN), Wireless Metropolitan Area Network, Wireless Wide Area Network and the like. The network 112 may be configured to work as the infrastructure that allows multiple powering devices 101-1, . . . , 101-N to connect and exchange information with a server 114.

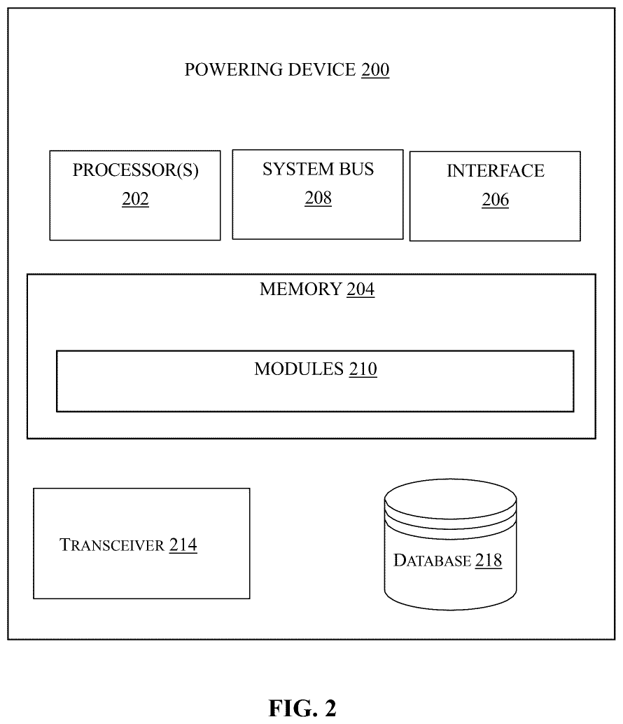

FIG. 2 illustrates a block diagram representation of a powering system 200, such as those shown in FIG. 1, for transferring power to another device using series resonant capacitive Electro-Quasi Static Human Body Powering (EQS-HBP), in accordance with an embodiment of the present disclosure. The powering system 200, is similar to the powering device 101 as shown in FIG. 1. The powering system 200, includes a processor 202. In an embodiment, the powering system 200 includes a memory 204 coupled to the processor 202, the memory 204 includes processor-executable instructions in the form of one or more modules 210.

The powering system 200 may further comprise transceiver 214 which acts as both transceiver and receiver to transfer power between other devices in the human body network. Referring to FIG. 2, the powering system 200 may comprise one or more processor(s) 202 that may be implemented as one or more microprocessors, microcomputers, microcontrollers, digital signal processors, central processing units, logic circuitries, and/or any devices that process data based on operational instructions. Among other capabilities, the one or more processor(s) 202 may be configured to fetch and execute computer-readable instructions stored in a memory 204 of the powering system 200. The memory 204 may be configured to store one or more computer-readable instructions or routines in a non-transitory computer readable storage medium, which may be fetched and executed to create or share data packets over a network service. The memory 204 may comprise any non-transitory storage device including, for example, volatile memory such as random-access memory (RAM), or non-volatile memory such as erasable programmable read only memory (EPROM), flash memory, and the like.

In an embodiment, the powering system 200 may include a communication interface(s) 206. The communication interface(s) 206 may comprise a variety of interfaces, for example, interfaces for data input and output (I/O) devices, storage devices, and the like. The communication interface(s) 206 may also provide a communication pathway for one or more components of the powering system 200.

In an embodiment, the memory 204 may include a plurality of modules 210 for performing one or more operations within the powering system 200.

The processor 202 is configured to execute program instructions. For example, the processor 202 may be a real processor or a virtual processor. It will be understood that the powering system 200 does not suggest any limitation as to the scope of use or functionality of the described embodiments. The powering system 200 may include, but is not limited to, one or more of a general-purpose computer, a programmed microprocessor, a microcontroller, an integrated circuit, and other devices or arrangements of devices that are capable of implementing the steps that constitute the methods of the present invention.

Exemplary embodiments of the powering system 200 in accordance with the present invention may include one or more servers, desktops, laptops, tablets, smartphones, mobile phones, mobile communication devices, tablets, phablets, and personal digital assistants. In an embodiment, the memory 204 may store software for implementing various embodiments of the present invention. The powering system 200 may include additional components or fewer components. For example, the powering system 200 may include one or more communication interfaces 206, one or more input devices, one or more output devices, a system bus 208 and a database 218. An interconnection mechanism (not shown) such as a bus, control circuitry, or network, interconnects the components of the powering system 200. In various embodiments, operating system software (not shown) provides an operating environment for various software(s) executing in the powering system 200 using the processor 202 and manages different functions and features of the components of the powering system 200.

The interface 206 allows communication over a conducting medium to various other computing entities. The interface 206 provides information such as program instructions, or other data in a conducting medium. The communication media may include, but are not limited to, wired or wireless methodologies implemented with electrical, optical, RF, infrared, acoustic, microwave, Bluetooth, IEEE 802.15.6, IEEE 802.15.4, IEEE 802.15.3 compliant networking protocols, or other transmission media.

The input device(s) may include, but are not limited to, a touch screen, a keyboard, mouse, pen, joystick, trackball, a voice device, a scanning device, or any other device that is capable of providing input to the powering system 200. The output device(s) may include, but not be limited to, a user interface on CRT, LCD, LED display, or any other display associated with any of servers, desktops, laptops, tablets, smartphones, mobile phones, mobile communication devices, tablets, phablets and personal digital assistants, printer, speaker, CD/DVD writer, or any other device that provides output from the powering system 200.

The database 218 may include, but not be limited to, magnetic disks, magnetic tapes, CD-ROMs, CD-RWs, DVDs, any types of computer memory, magnetic stripes, smart cards, printed barcodes, or any other transitory or non-transitory medium which may be used to store information and may be accessed by the powering system 200. In various embodiments, the database 218 may contain program instructions for implementing any of the described embodiments.

FIG. 3 is a schematic representation of a plurality of example ground electrode configurations 300 of transmitter 102 and receiver 104, in accordance with an embodiment of the present disclosure. Part (A) of FIG. 3 depicts a ground configuration of the ground electrode at the transmitter 102 and the receiver 104. Specifically, Part (A) of FIG. 3 depicts a ground-connected transmitter (Tx) 102 and a ground-connected receiver (Rx) 104. In this configuration, both the transmitter 102 and receiver 104 are connected to the environmental ground.

The body acts as a conducting medium 106, transferring EQS signals from the transmitter 102 to the receiver 104. Since the transmitter 102 is ground-connected, the voltage of the body 106 closely matches the transmitted voltage. The receiver 104 being ground-connected allows for efficient power transfer, as the differential voltage between the signal and ground electrodes at the receiver 104 is maximized. This configuration likely provides stable and efficient power delivery due to the common ground reference between TX 102 and RX 104.

Part (B) of FIG. 3 depicts a ground-connected transmitter (Tx) 102 and ground-floated receiver (Rx) 104. The transmitter 102 is ground-connected, where the body voltage is approximately equal to the transmitted voltage. Further, the receiver 104 is ground-floated, where its ground electrode is not directly connected to the environmental ground. In this case, the receiver 102 relies on parasitic capacitance (Cpp) between its ground electrode and the environment to complete the circuit. Since the receiver ground is floating, the induced voltage at the receiver 104 may be reduced, potentially affecting power transfer efficiency. This configuration is useful for applications where a ground connection is not feasible at the receiver end.

Part (C) of FIG. 3 depicts a ground-floated transmitter (Tx) 102 and ground-connected receiver (Rx) 104. The transmitter 102 is ground-floated, where its ground electrode is isolated from the environmental ground. The receiver 104 is ground-connected, providing a stable reference for power extraction. In this case, the body voltage is determined by the capacitance ratio between the transmitter's parasitic capacitance (Cᵣₑₜ) and the body capacitance (C_{body}), leading to a reduction in the effective body voltage. As the transmitter 102 is floating, the body voltage is significantly lower than in the ground-connected case.

Part (D) of FIG. 3 depicts a ground-floated transmitter (tx) 102 and ground-floated receiver (rx) 104. Both the transmitter 102 and receiver 104 are ground-floated, where neither has a direct connection to the environmental ground. The power transfer in this configuration relies entirely on capacitive coupling, including the parasitic capacitances between the transmitter 102, receiver 104, and the environment. Since both ground electrodes are floating, the differential voltage at the receiver 104 may be further reduced due to limited capacitive coupling. This setup is the most challenging for efficient power transfer, as it depends on the balance between Cₚₚ (parasitic capacitance between received signal and receiver ground) and Cᵣₑₜ (return capacitance between receiver ground and environmental ground). Power optimization in this case may require impedance matching techniques to maximize energy transfer.

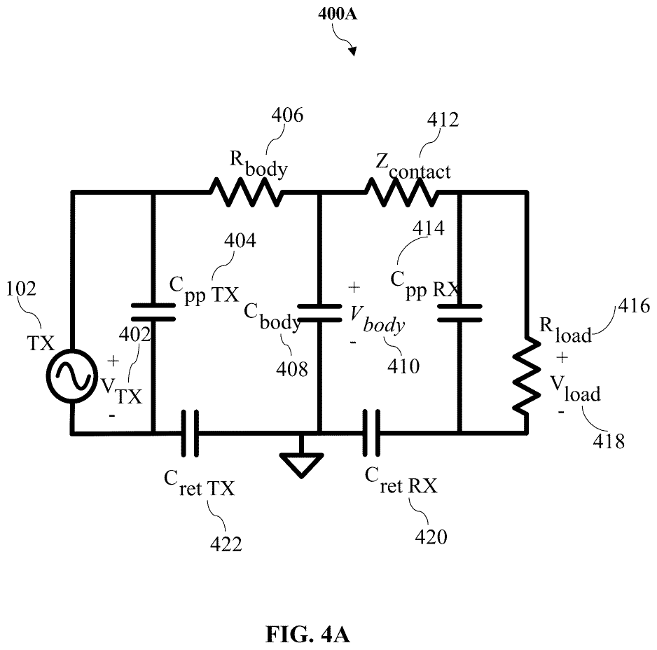

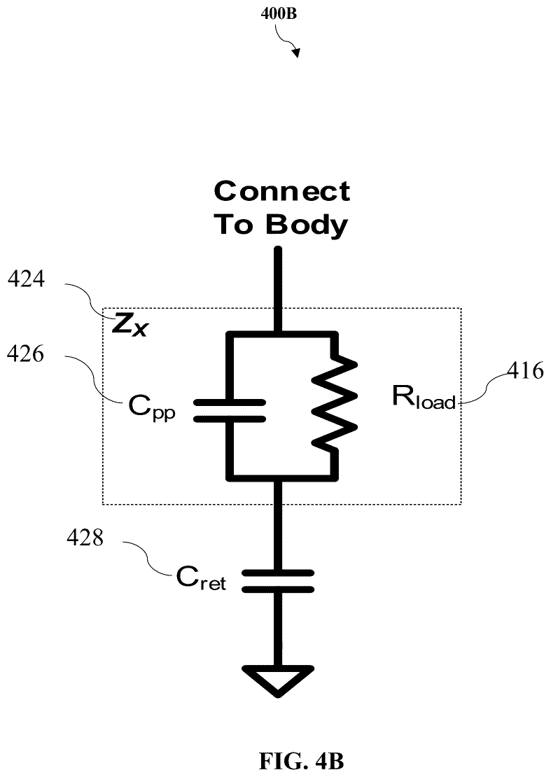

FIGS. 4A-B are circuit diagram representations of an original EQS-HBP lumped circuit 400 with a human body 106, where the transmitter 102 and the receiver 104 are depicted as ground-floated devices, in accordance with an embodiment of the present disclosure. On the TX side, the voltage 402 coupled to the body is characterized as:

$$\\ \begin{matrix}{V}_{body} = {V}_{tx} * \frac{{C}_{ret}}{{C}_{ret} + {C}_{body}} & equation ( 1 )\end{matrix}$$

As Cᵣₑₜ typically exists in lower picofarad ranges (e.g. 1 pF) and C_{body} typically exists in high 10s to 100s of picofarad ranges (e.g. 100 pF), this capacitive division introduces a near 40 dB drop in voltage transmitted to voltage coupled to the human body 106.

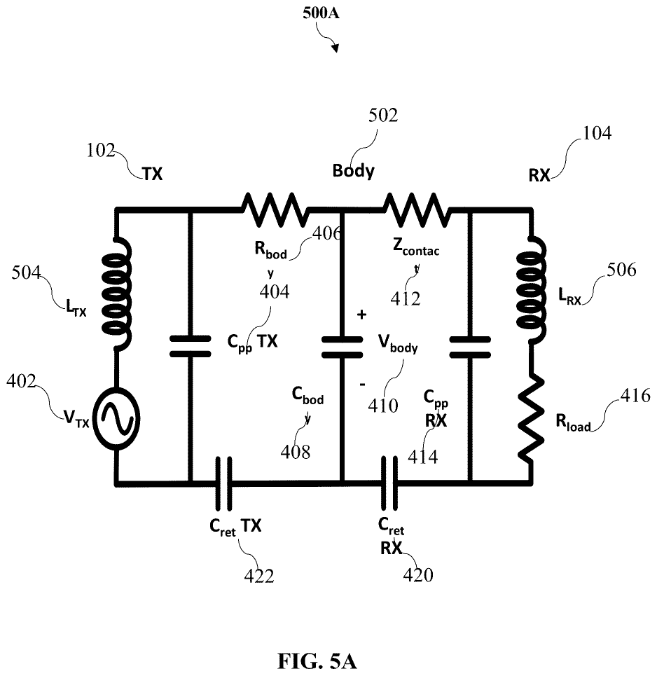

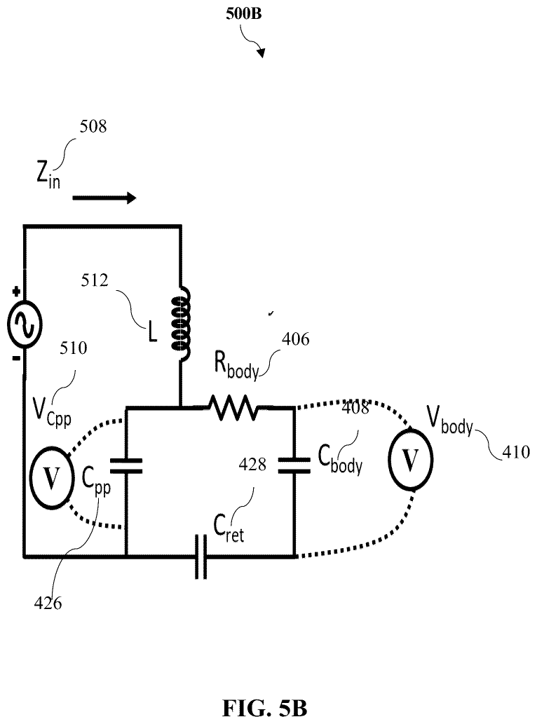

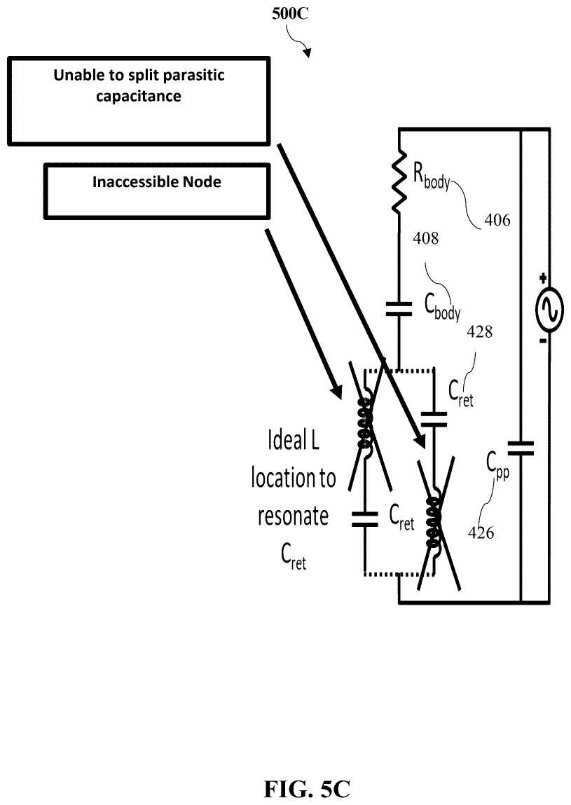

FIG. 5A is a circuit diagram representation of series resonance configuration 500a for both transmitter 102 and receiver 104, in accordance with an embodiment of the present disclosure. By introducing a series inductor 110, the voltage coupled to the body 106 may be altered as below at the frequency of resonance:

$$\\ \begin{matrix}{V}_{body} = Q * {V}_{tx} * \frac{{C}_{ret}}{{C}_{ret} + {C}_{body}} & equation ( 2 )\end{matrix}$$

The frequency of resonance is determined by the size of inductor 110 with the size of the capacitor parallel to the transmitting source 108. Therefore, series resonance on the TX side boosts its ability to couple more voltage onto the human body 106. However, the inductor capacitor (LC) resonance formed would also drastically lower the impedance of the parallel capacitor at the point of resonance. To optimize the amount of current drawn from the transmitting source 108, another inductor 110 may be added in parallel to the parallel capacitor to reduce current drawn on this branch. On the RX side, the series connected inductor 110 may cancel the effect of Cᵣₑₜ to boost the received voltage and power. Before the introduction of the inductor 110, the input impedance into the RX branch is:

$$\\ \begin{matrix}{Z}_{in} = {Z}_{{C}_{ret}} + {Z}_{X} = - \frac{j}{ω {C}_{ret}} + {Z}_{X} & equation ( 3 )\end{matrix}$$

Where Zₓ represents the combined impedance of Cₚₚ and Z_{load}. In order to boost the power received, it is necessary to reduce the effect of Cᵣₑₜ. This is because Cᵣₑₜ typically exists in the small picofarads range (e.g. 1 pF) and thus it has really high AC impedance at EQS frequencies (>100 k Ohms). The series-connected inductor 110 introduces a positive reactive components as illustrated below:

$$\\ \begin{matrix}{Z}_{X} = {Z}_{{C}_{pp}} // ( {Z}_{L} + {R}_{load} ) = \frac{{R}_{load} + L ω j}{1 - {ω}^{2} {C}_{pp} L + {R}_{load} {C}_{pp} ω j} & equation ( 4 )\end{matrix}$$

Consequently, series inductor 110-1 on the TX side may boost the voltage and power coupled to the human body 106 and on the RX side may boost the voltage and power received from the human body 106. In combination, series inductor 110 may significantly improve the power transferred from the TX 102 to the RX 104.

The quality factor (Q) of the inductors 110 used in the series resonance technique plays a significant role in the system's performance. A higher Q factor minimizes energy losses and enhances power delivery to the load 116. At the RX 104, a high Q factor reduces resistance in series with the load 116, thereby improving the received power. At the TX 102, a high Q factor ensures lower voltage drops across the source impedance, enabling more effective voltage coupling onto the body 106.

FIG. 5B is a circuit diagram representation of an alternative representation of the transmitter series resonance circuit, emphasizing resonance and the invariance of the V_{body}/V_{Cpp} ratio across frequencies, in accordance with an embodiment of the present disclosure.

FIG. 5C is a circuit diagram representation of optimal placement of an inductor to cancel effect of Cᵣₑₜ through resonance, in accordance with an embodiment of the present disclosure.

In an example embodiment, the TX series resonance increases the power transmitted into the body 106. This may be observed from FIG. 5B As the inductor 110 is in resonance with a combination of Cₚₚ 426 branch and C_{body} 408 and Cᵣₑₜ 428 branch, the impedance 508 seen from the TX source 108 (Zᵢₙ 508 as shown in FIG. 5B) into the circuit is reduced, and the current flowing out of the TX source increases. With the increase in current flowing through both branches, the voltage 510 across the two branches increases, and it is shown that V_{C}_{ₚₚ}=Q*Vₜₓ [6]. As R_{body}<<Z_{C}_{ᵣₑₜ}, the voltage across the body 410 may be approximated as (shown in FIG. 5B):

$$\\ \begin{matrix}{V}_{body} = Q * {V}_{tx} * \frac{{C}_{ret}}{{C}_{ret} + {C}_{body}} & equation ( 6 )\end{matrix}$$

Furthermore, another inductor (not shown) may be added in parallel to Cₚₚ to reduce the shunt current through it at resonance to achieve higher efficiency, and the series-connected inductor may need to increase inductance in order to maintain the same resonant frequency.

Despite the increase in V_{body} 410 due to resonance, series or a combination of series and parallel resonance may not be able to cancel the effect of Cᵣₑₜ 428 for TX 102. As Cᵣₑₜ 428 is in series with C_{body} 408, the voltage across C_{body} (V_{body} 410) experiences a capacitive division that causes V_{body} 410 to be nearly 40 dB lower than the resonant voltage QVₜₓ, which is the same as V_{C}_{ₚₚ} 510. For reference, C_{body} 408 exists in the high 10s of pico-farads (e.g., around 100 pF), and Cᵣₑₜ 428 exists in the lower pico-farads (e.g., around 1 pF). In order to effectively boost TX ability to couple voltage onto the body, it would be ideal to use resonance to cancel Cᵣₑₜ 428 into a short-circuit to remove this capacitive division effect. Resonating out Cᵣₑₜ requires placing inductors in series with it, and two configurations of that are shown in FIG. 5C. However, both configurations are not possible as C_{body} 408, Cᵣₑₜ 428 and Cₚₚ 426 are parasitic capacitance formed by parasitic coupling between electrodes, environmental ground, and the body surface. This means that it is impossible to insert an inductor in between C_{body} 408 and Cᵣₑₜ 428 and also impossible to split Cᵣₑₜ 428 and Cₚₚ 426 connection by an inductor. Thus, series resonance for the TX 102 is unable to cancel the effect of Cᵣₑₜ, 428 unlike that for the RX 104.

Circuit simulation has been performed to elucidate this concept further. For RX 104, the goal is to maximize voltage across R_{load}(Vᵣₓ) 406 given the same V_{body} 410. For TX 102, the goal is to maximize V_{body} 410 given the same Vₜₓ.

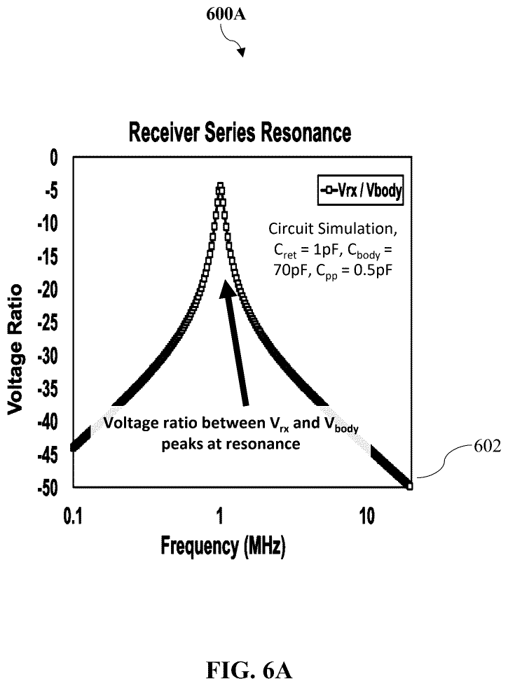

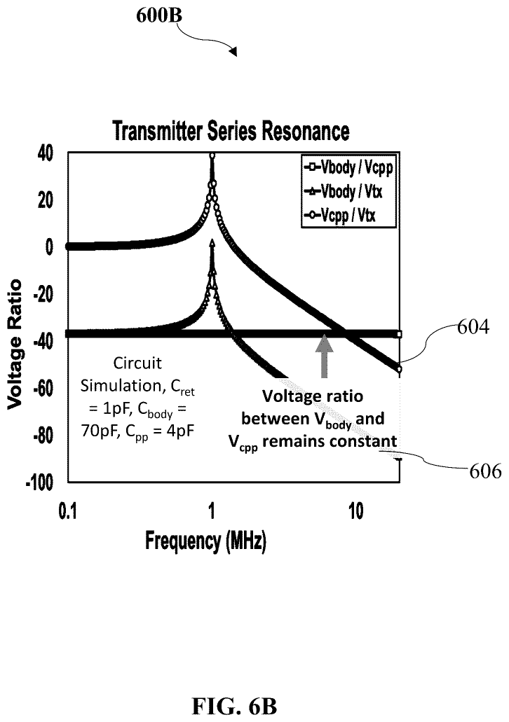

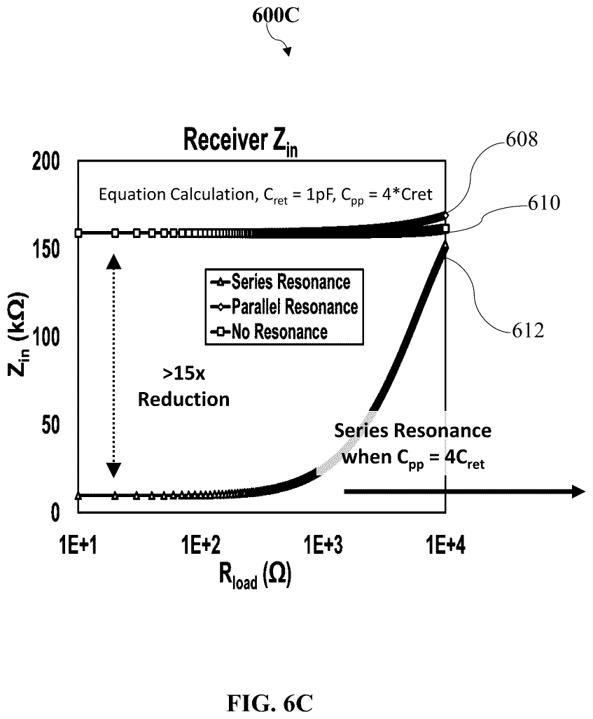

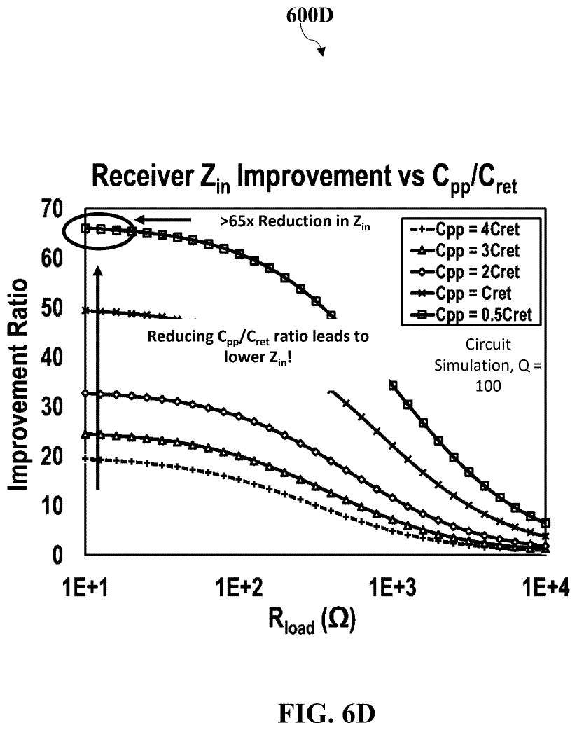

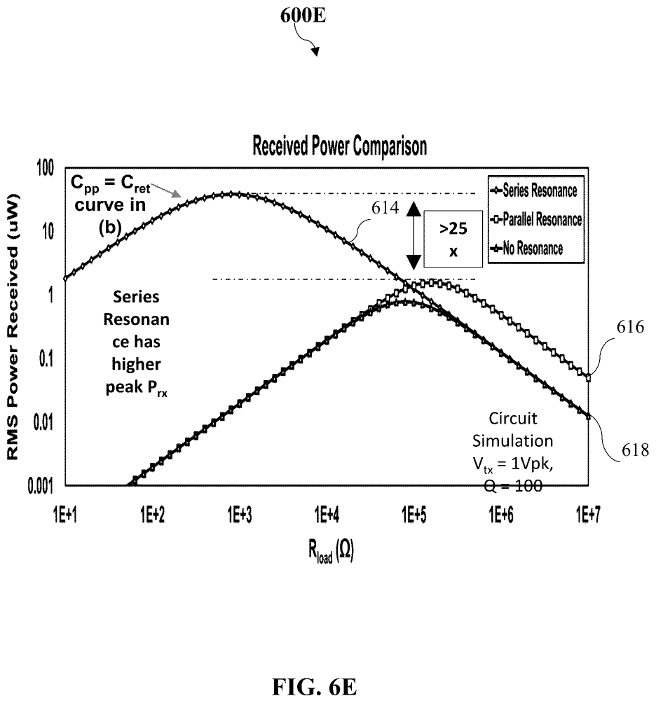

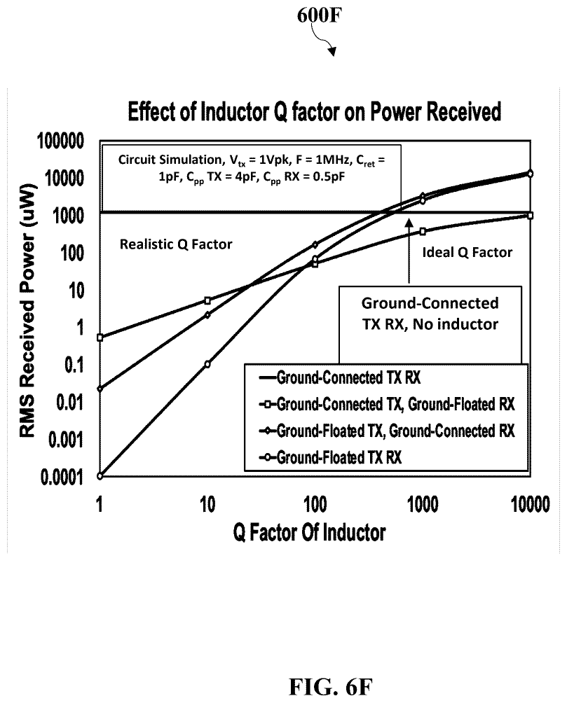

FIG. 6A is a graphical representation of voltage ratio Vᵣₓ/V_{body} for a ground-floated RX with series resonance, in accordance with an embodiment of the present disclosure. In FIG. 6A which shows RX series resonance 602,

$$\\ \frac{{V}_{rx}}{{V}_{body}}$$

peaks at the resonant frequency, showing the effect of canceling Cᵣₑₜ as more on-body voltage gets received across R_{load}.

FIG. 6B is a graphical representation of three voltage ratios for a ground-floated TX: V_{body}/V_{Cpp}, V_{body}/Vₜₓ 606, and V_{Cpp}/Vₜₓ 604, in accordance with an embodiment of the present disclosure. In FIG. 6B, which shows TX series resonance, the voltage ratio between V_{body}/Vₜₓ 606 does improve at the resonant point. However, the voltage ratio of

$$\frac{{V}_{body}}{{V}_{{C}_{pp}}}$$

remains constant across frequency, showing the lack of Cᵣₑₜ cancellation for the TX 102. In combination, the TX 102 is coupling voltage onto the body where series resonance does boost current into the body but cannot cancel the capacitive division between Cᵣₑₜ and C_{body}, and the RX 104 is receiving voltage from the body to drive R_{load} where series resonance may cancel part of the Cᵣₑₜ to significantly reduce the RX Zᵢₙ and boost the received voltage. A combination of the series resonance from the TX and RX side is shown in FIG. 5A. Practically, due to the limited inductor Q factor, series resonance for the TX 102 is unlikely to overcome the near 40 dB voltage reduction from the capacitive division, and V_{body} is unlikely to exceed Vₜₓ.

FIG. 6C is a graphical representation of Zᵢₙ for series, parallel, and no resonance configurations, all with the same RX parasitic capacitances (Cₚₚ=4 pF and Cᵣₑₜ=1 pF), in accordance with an embodiment of the present disclosure. FIG. 6D is a graphical representation of improvement in Zᵢₙ (Zᵢₙ parallel resonance 608/Zᵢₙ series resonance 612) across typical Cₚₚ/Cᵣₑₜ ratios, in accordance with an embodiment of the present disclosure. FIG. 6E is a graphical representation of Pᵣₓ versus R_{load} for series, parallel, and no resonance 610 configurations under the same conditions as in FIG. 6C, in accordance with an embodiment of the present disclosure.

Circuit simulations with identical parasitic components have shown that series resonance achieves higher Pᵣₓ compared to parallel resonance or no resonance, as seen in FIG. 6E. To understand the circuit theory behind this, it is essential to consider what the inductor is resonating with. In parallel resonance, the inductor forms a clear LC tank with Cₚₚ, and at resonance, the shunt current that would normally flow through Cₚₚ in the absence of resonance instead flows through R_{load}, thereby boosting Pᵣₓ. In series resonance, the LC tank is formed by the inductor along with a combination of Cₚₚ and Cᵣₑₜ. At resonance, a portion of the Cᵣₑₜ is canceled, significantly increasing the input current and enhancing the Pᵣₓ.

This may be intuitively illustrated with circuit equations of RX Zᵢₙ:

$${Z}_{i n} = {Z}_{{C}_{ret}} + {Z}_{X} = - \frac{j}{ω {C}_{ret}} + {Z}_{X} \qquad equation ( 7 )$$

In Eqn 7, Z_{X}: represents the equivalent impedance of the remaining circuit components that are in series to Cᵣₑₜ. As

$${Z}_{{C}_{ret}} = \frac{1}{ω {C}_{ret}} ,$$

it has a negative reactive component and as Cᵣₑₜ is small, the absolute magnitude of Z_{C}_{ᵣₑₜ} is large. If a positive reactive component may be introduced to the Z_{X} term to cancel out part of the negative reactive component from the Z_{C}_{ᵣₑₜ} term, overall Zᵢₙ may be reduced.

For parallel resonance, its Z_{X} is:

$${Z}_{{X}_{parallel}} = \frac{\frac{\underline{{R}_{load}}}{\underline{{Z}_{L}}}}{{Z}_{{C}_{pp}}} = \frac{{LR}_{load}}{{jR}_{load} ω ( {LC}_{pp} - \frac{1}{{ω}^{2}} ) + L} \qquad equation ( 8 )$$

$$At resonance ( ω = \frac{1}{\sqrt{{LC}_{pp}}} ) : Im ( {ZX}_{parallel} ) = 0 \qquad equation ( 9 )$$

The above equation would not have positive reactive components at resonance, corresponding to the major limitation of parallel resonance: it does not cancel Cᵣₑₜ. Therefore, the lowest Zᵢₙ for parallel resonance remains at Z_{C}_{ᵣₑₜ}.

For series resonance, its Zₓ is:

$${Z}_{{X}_{series}} = \frac{\underline{{Z}_{{C}_{pp}}}}{{Z}_{L} + {R}_{load}} = \frac{{R}_{load} + L ω j}{1 - {ω}^{2} {C}_{pp} L + {R}_{load} {C}_{pp} ω j} \qquad equation ( 10 )$$

$$At resonance ( ω = \frac{1}{\sqrt{L ( {C}_{ret} + {C}_{pp} )}} ) : Im ( {Z}_{{X}_{series}} ) > 0 \qquad equation ( 11 )$$

At resonance, the above equation would have positive reactive components due to the Lωj term in the numerator. This may be easily verified by substituting the variables with actual circuit values. Consequently, part of the Cᵣₑₜ gets cancelled by series resonance, and Zᵢₙ may thus be lower than Z_{C}_{ᵣₑₜ}. The Zᵢₙ improvement is dependent on R_{load} as it restricts the inductor resonance current. When R_{load} 416 is significantly large, it will stop series resonance and transform the circuit back to no resonance, as shown in FIGS. 6D and 6E. The Zᵢₙ for series resonance may be derived as shown below:

$${Z}_{in} = \sqrt{\frac{{k}_{4} + {k}_{5} {R}_{load}^{2}}{{k}_{2} {R}_{load}^{2} + {k}_{3}}} \qquad equation ( 12 )$$

$${k}_{2} = {( {ω}^{2} {C}_{pp} {C}_{ret} )}^{2} \qquad equation ( 13 )$$

$${k}_{3} = {( ω {C}_{ret} - {ω}^{3} {C}_{pp} {C}_{ret} L )}^{2} \qquad equation ( 14 )$$

$${k}_{4} = {( 1 - {ω}^{2} L ( {C}_{ret} + {C}_{pp} ) )}^{2} \qquad equation ( 15 )$$

$${k}_{5} = {( ( {C}_{ret} + {C}_{pp} ) ω )}^{2} \qquad equation ( 16 )$$

FIG. 6C compares Zᵢₙ across different resonance techniques. The parallel resonance Zᵢₙ closely resembles that of no resonance at low to moderate R_{load}. As R_{load} is parallel to Cₚₚ, the effect of Cₚₚ is negligible if Z_{C}_{ₚₚ}>>R_{load}. Thus, Zᵢₙ≈Z_{C}_{ᵣₑₜ} when R_{load}<<Z_{C}_{ᵣₑₜ}.

With parallel resonance, the LC tank behaves as an open circuit, making the simplified circuit resemble that of no resonance. In contrast, the series resonance Zᵢₙ is significantly lower. Depending on the ratio between Cₚₚ and Cᵣₑₜ, it may reach values as low as 2 kΩ or lower, which represents a reduction of over 65× compared to the Zᵢₙ of parallel resonance and no resonance 618, as shown in FIG. 6D. This substantial reduction in Zᵢₙ greatly increases the current into RX, enabling higher peak Pᵣₓ, as also observed in FIG. 6E. Series resonance 614 achieves a higher peak power than parallel resonance 616, with the optimal R_{load} for maximum Pᵣₓ occurring at a lower R_{load}.

Additionally, for device form factor optimization, the ratio between Cₚₚ and Cᵣₑₜ is a crucial parameter. As shown in FIG. 6D, Zᵢₙ is a strong function of

$$\frac{{C}_{pp}}{{C}_{ret}} .$$

If Cₚₚ≤Cᵣₑₜ, series resonance will be more effective at reducing Zᵢₙ and boosting Pᵣₓ.

Lastly, because RX series resonance significantly reduces Zᵢₙ, with an optimized Cₚₚ to Cᵣₑₜ ratio, Zᵢₙ may approach R_{load}. The body 106 may no longer be considered as equipotential when Z_{in rx} is comparator to R_{body}+Z_{contact}. This suggests that R_{body}+Z_{contact} should be included in circuit simulation to improve simulation accuracy.

In conclusion, when the RX 104 is ground-floated, a series-connected inductor significantly enhances the Pᵣₓ by partially cancelling Z_{C}_{ᵣₑₜ}, thereby reducing the RX Zᵢₙ. For a ground-connected RX 104, if Z_{contact} 412 is minimized by increasing the contact area, there is little difference between parallel and no resonance, as Z_{C}_{ₚₚ}>R_{load}.

FIG. 6F is a graphical representation of effect of the inductor Q factor on the Pᵣₓ, where there is a circuit simulation across four configurations of capacitive EQS-HBP where an inductor is used and C_{body}=70 pF, Cᵣₑₜ=1 pF, Cₚₚₜₓ=4 pF, Cₚₚᵣₓ=1 pF, in accordance with an embodiment of the present disclosure. As the previous subsection introduces the use of an inductive element to achieve higher Pᵣₓ, the effect of the inductor quality factor on the Pᵣₓ is investigated in this subsection. FIG. 6F shows that across the capacitive EQS-HBP where an inductor is used, having a higher quality factor increases the Pᵣₓ tremendously.

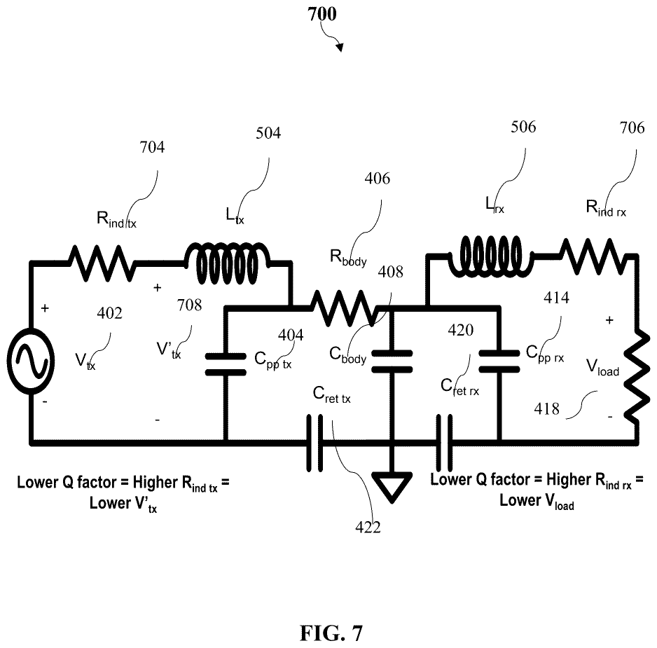

FIG. 7 is a circuit diagram representation of an inductor with Q factor modelled as R_{ind} for both TX 102 and RX 104, in accordance with an embodiment of the present disclosure. When inductive resonance is used on the TX 102 side, the quality factor may be modeled as a series connected R_{ind} 704 to the inductor 504, as shown in FIG. 7. With a high-quality inductor, this R_{ind} 704 is small, and the voltage drop across R_{ind} is low, with the LC circuit having the majority of the Vₜₓ 402. However, with a low-quality inductor, this R_{ind} 704 is large, and the voltage drop across it is high, with the LC circuit having only a fraction of the Vₜₓ 402. Furthermore, when the quality factor is high, V_{body} may be higher than Vₜₓ 402, causing the two ground-floated TX configurations to have a higher Pᵣₓ than ground-connected TX and RX received cases at high Q factor regions.

When inductive cancellation is used on the RX 104 side, the inductor Q factor determines the amount of R_{ind} 706 series connected with the Road, as shown in FIG. 7. If the Q factor is high, R_{ind} is kept low with less Pᵣₓ dissipated by it. As RX inductive cancellation does not boost V_{body}, the highest achievable Pᵣₓ is similar to that of the ground-connected TX 102 and RX 104 case, with an ideal inductor.

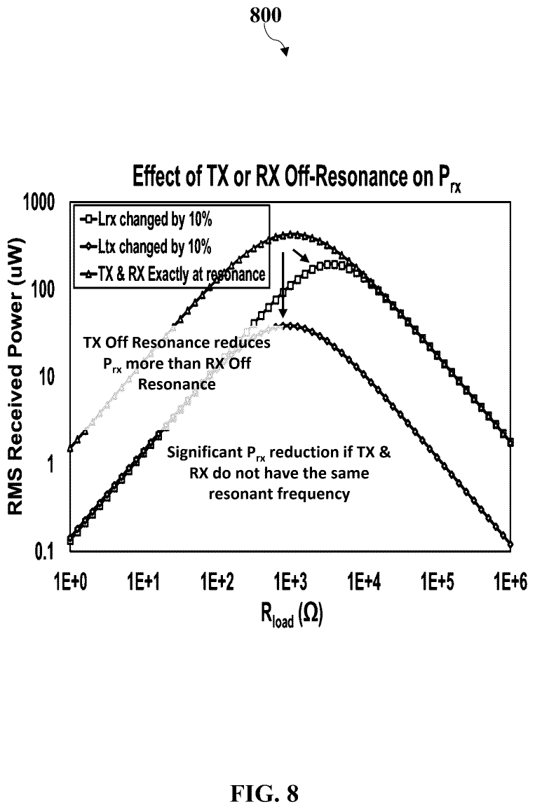

FIG. 8 is a graphical representation depicting an effect of transmitter or receiver off-resonance on Pᵣₓ, in accordance with an embodiment of the present disclosure. Operating below 30 MHz, the powering system 100 ensures that the electromagnetic wavelength exceeds human body dimensions, maintaining an electro-quasistatic approximation. Resonance alignment between TX 102 and RX 104 frequencies is critical to achieving peak performance. To be exact, resonance alignment refers that the TX transmitting frequency should aligned with the TX series resonance frequency and be aligned with the RX resonance frequency. FIG. 8 shows that power transferred is optimized when TX and RX frequencies are aligned.

The optimal loading resistance is determined by considering the interplay between the reactive components introduced by the inductor 110 and the capacitive elements in the system 100. At resonance, the inductive reactance and capacitive reactance effectively cancel each other, leaving only the resistive components to dictate power transfer. The optimal loading resistance is:

$${R}_{load opt} = max ( {R}_{ind} , {R}_{body} + {Z}_{contact} , {Z}_{{C}_{ret residual}} ) \qquad equation ( 17 )$$

$${Z}_{{C}_{ret residual}} \approx \frac{{k}_{3} {k}_{5} - 3 {k}_{2} {k}_{4} - \sqrt{{( 3 {k}_{2} {k}_{4} - {k}_{3} {k}_{5} )}^{2} - 4 {k}_{2} {k}_{3} {k}_{4} {k}_{5}}}{2 {k}_{2} {k}_{5}} \qquad equation ( 18 )$$

$${k}_{2} = {( {ω}^{2} {C}_{pp} {C}_{ret} )}^{2} \qquad equation ( 19 )$$

$${k}_{3} = {( ω {C}_{ret} - {ω}^{3} {C}_{pp} {C}_{ret} L )}^{2} \qquad equation ( 20 )$$

$${k}_{4} = {( 1 - {ω}^{2} L ( {C}_{ret} + {C}_{pp} ) )}^{2} \qquad equation ( 21 )$$

$${k}_{5} = {( ( {C}_{ret} + {C}_{pp} ) ω )}^{2} \qquad equation ( 22 )$$

This may be further split into four sub scenarios. In the first scenario, when the frequency alignment is perfect and inductor Q factor is high (for example, >=50), the Z_{C}_{_{ret residual}} is low and R_{ind} is also low, the optimal loading resistance may be approximated by R_{body}+Z_{contact}. In the second scenario, when the frequency alignment is perfect but the inductor Q factor is low, the R_{ind}>>R_{body}+Z_{contact}, thus, the optimal loading resistance is R_{ind}. In the third scenario, when the frequency alignment is imperfect and the inductor Q factor is high, the Z_{C}_{_{ret residual}}>>R_{body}+Z_{contact}, thus the optimal loading resistance is Z_{C}_{_{ret residual}}. In the last scenario, when the frequency alignment is imperfect and the inductor Q factor is low, the R_{ind}>>Z_{C}_{_{ret residual}}, thus the optimal loading resistance is R_{ind}.

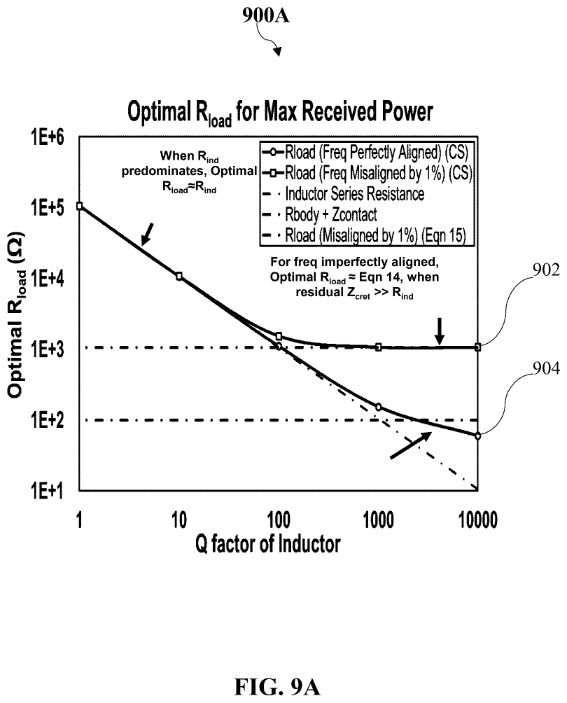

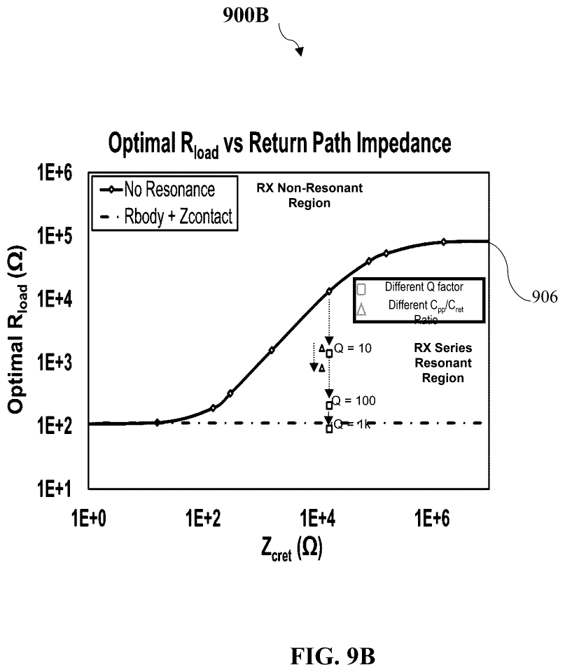

FIG. 9A is a graphical representation of an optimal R_{load} that maximizes Pᵣₓ across two scenarios: perfect and imperfect frequency alignment between TX and RX series resonance frequency, in accordance with an embodiment of the present disclosure. The powering system 200 supports versatile configurations, including floating ground electrodes for minimal environmental grounding requirements and ground-connected electrodes for enhanced stability and reduced impedance. These configurations enable flexible implementation across diverse application scenarios and environments. FIG. 9A shows that by having ground-connected electrode may optimize the power transferred further.

Compared to existing techniques, the present method provides higher energy density due to the higher power transferred. By integrating series and parallel resonance techniques and providing detailed analysis of TX 102 and RX 104 configurations, the present disclosure represents a transformative solution for capacitive EQS-HBP systems. The ability to optimize power transfer, adapt to various configurations, and maintain efficient operation across challenging scenarios ensures that the powering system 100 may be applicable to a wide range of battery-less on-body devices.

FIG. 9B is a graphical representation of an optimal R_{load} that maximizes Pᵣₓ across different return path impedance, covering from ground-connected RX to ground-floated RX, in accordance with an embodiment of the present disclosure.

With the biophysical circuit model and series resonance technique established in previous sections, this subsection investigates the optimal R_{load} for maximizing Pᵣₓ across different configurations of capacitive EQS-HBP. The four configurations may be effectively reduced to two primary cases: RX 104 as either ground-floated or ground-connected, with TX 102 ground-connected in both scenarios. As demonstrated earlier, resonance does not mitigate the effect of Cᵣₑₜ for a ground-floated TX 102. Consequently, the on-body voltage at the ground-floated TX contact point is determined solely by the ratio of Cᵣₑₜ TX to C_{body} and remains unaffected by R_{body}, Z_{contact}, or the RX ground connection. Thus, the ground-floated TX 102 may be modeled as a ground-connected TX 102 with a reduced Vₜₓ. Although ground-connected TX Z_{contact} may vary V_{body} with different RX Zᵢₙ, ground-connected TX 102 generally have much more relaxed sizing constraints compared to RX 104, leading to Z_{contact TX}<<R_{body}, reducing the importance of this issue. Thus, Z_{contact TX} is approximated as negligible.

For the configuration where both TX 102 and RX 104 are ground-connected, Pᵣₓ may be approximated as:

In below equation, maximum Pᵣₓ is achieved when R_{load}=R_{body}+Z_{contact}. Additionally, Pᵣₓ is inversely proportional to R_{body}+Z_{contact}, highlighting the importance of minimizing Z_{contact} to enhance Pᵣₓ.

In the configuration where the RX 104 is ground-floated and the TX 102 is ground-connected with series resonance, resonance alignment and inductor Q factor significantly influence optimal R_{load}. When the RX resonant frequency aligns perfectly with the TX frequency, and the inductor Q factor is high with a large

$$\frac{{C}_{ret}}{{C}_{pp}}$$

ratio, Cᵣₑₜ may be effectively canceled, enabling Zᵢₙ≈R_{load}. This transforms the ground-floated RX 104 into a ground-connected configuration. As shown in below equation, peak Pᵣₓ occurs when R_{load}=R_{body}+Z_{contact}, illustrated by the red curve 904 in FIG. 9A with an idealized Q factor approaching infinity.

However, when the inductor Q factor is low, as detailed in the previous subsection, the non-ideal inductor may be modeled as a perfect inductor in series with Ring. While the ideal inductor cancels Z_{C}_{ᵣₑₜ}, the RX Zᵢₙ becomes R_{ind}+R_{load}. If R_{ind}>>R_{body}+Z_{contact}, then Zᵢₙ>>R_{body}+Z_{contact}, and peak Pᵣₓ occurs when R_{load} matches R_{ind}, as shown in FIG. 9A for low Q factor regions. Practical misalignment between TX and RX frequencies further complicates performance. Minor frequency mismatches lead to incomplete cancellation of Cᵣₑₜ, and as the Q factor of a misaligned RX approaches infinity, RX Zᵢₙ=R_{load}+Z_{C}_{_{ret residual}}. Since Z_{C}_{ᵣₑₜ} residual>>R_{body}+Z_{contact} due to the small capacitance of Cᵣₑₜ, peak Pᵣₓ occurs when R_{load} matches Z_{C}_{_{ret residual}}, calculable using parameters k₄-k₅ defined in equation 23:

$${R}_{load opt}^{2} \approx \frac{{k}_{3} {k}_{5} - 3 {k}_{2} {k}_{4} - \sqrt{{( 3 {k}_{2} {k}_{4} - {k}_{3} {k}_{5} )}^{2} - 4 {k}_{2} {k}_{3} {k}_{4} {k}_{5}}}{2 {k}_{2} {k}_{5}} \qquad equation ( 23 )$$

In summary, the optimal R_{load} for a ground-floated RX with series resonance may be expressed as:

$${R}_{load opt} = max ( {R}_{ind} , {R}_{body} + {Z}_{contact} , {Z}_{{C}_{ret residual}} ) \qquad equation ( 24 )$$

In the absence of resonance, Pᵣₓ may be approximated as:

$${P}_{rx} = \frac{1}{{Z}_{load}} \cdot {( {V}_{tx} \cdot \frac{{Z}_{load}}{{Z}_{load} + {R}_{body} + {Z}_{contact} + {Z}_{{C}_{ret}}} )}^{2} \qquad equation ( 25 )$$

As Z_{C}_{ᵣₑₜ}>R_{body}+Z_{contact}, the denominator may be simplified to Z_{load}+Z_{C}_{ᵣₑₜ}, where Z_{load}=Z_{C}_{ₚₚ}∥R_{load}. When Z_{C}_{ᵣₑₜ}<Z_{C}_{ₚₚ}, peak Pᵣₓ occurs at R_{load}≈Z_{C}_{ᵣₑₜ} as Z_{C}_{ₚₚ} may be disregarded, shown in FIG. 9B in the Cᵣₑₜ-limited region. In contrast, when Z_{C}_{ᵣₑₜ}>>Z_{C}_{ₚₚ}, the peak Pᵣₓ occurs at R_{load}≈Z_{C}_{ₚₚ} as V_{load} saturates with further R_{load} increment, shown in FIG. 9B Cₚₚ-limited region.

In summary, FIG. 9B provides a comprehensive plot of this analysis. RX series resonance reduces the optimal R_{load}, with the extent of reduction primarily influenced by the inductor Q factor and the ratio of Cᵣₑₜ to Cₚₚ. Given that the ratio of Cᵣₑₜ to Cop varies less significantly than the inductor Q factor, optimizing the inductor Q factor is more critical. Additionally, R_{body}+Z_{contact} sets a lower limit on the optimal R_{load}, highlighting the importance of minimizing Z_{contact}, as a lower optimal R_{load} typically leads to an increase in Pᵣₓ.

Finally, while Eqn 24 approximates R_{load} accurately in regions with clear maxima, it may not precisely predict R_{load} near the intersection of R_{ind} with either R_{body}+Z_{contact} or Z_{C}_{_{ret residual}}. Further research is needed to refine this. In practical applications, human motion introduces fluctuations in Cᵣₑₜ and Cₚₚ, necessitating dynamic adjustments to the TX 102 or RX 104 resonant frequency to mitigate frequency misalignment and adjustments to R_{load} in response to these variations. This subsection, therefore, establishes approximate values and bounds for optimal R_{load}, providing a foundation for designing such an adaptive algorithm.

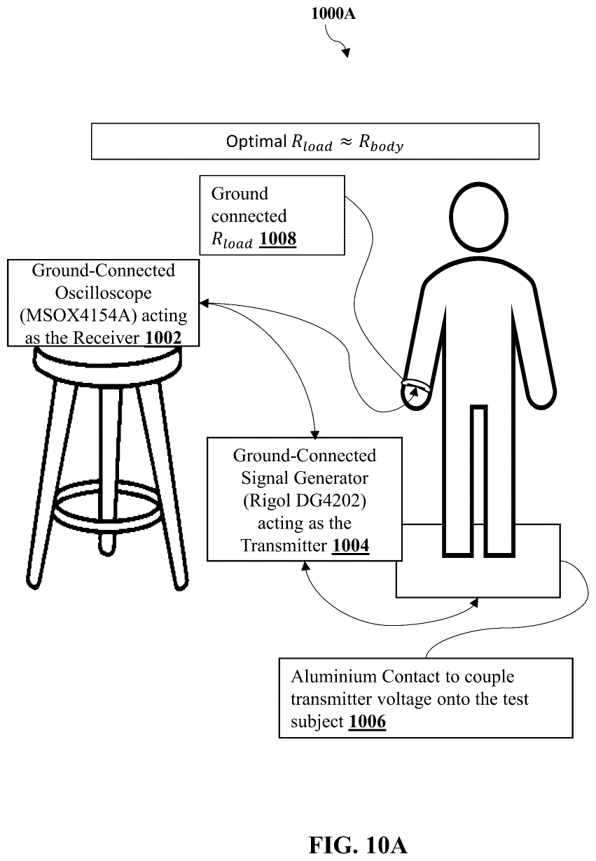

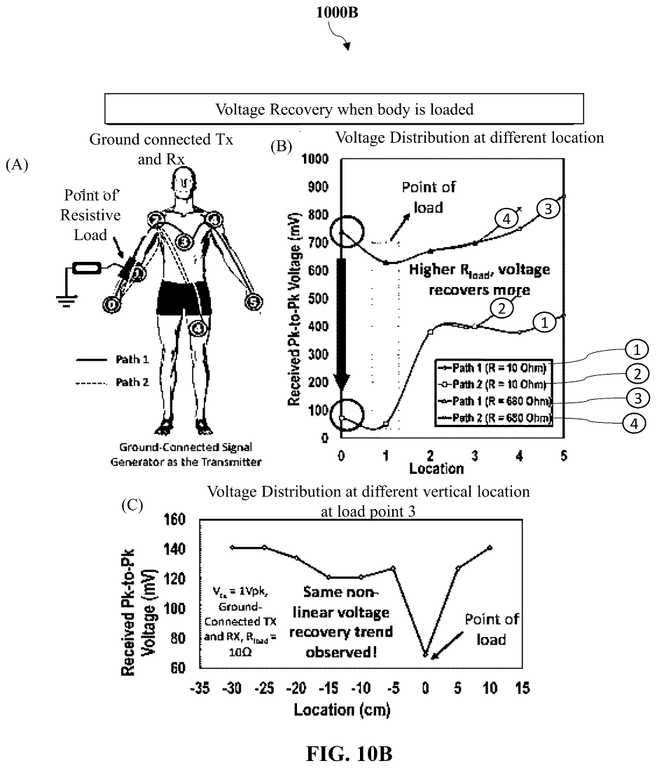

FIG. 10A is an experimental setup and comparative results of RX series versus parallel resonance showing that series resonance has higher peak Pᵣₓ than parallel resonance and the impact of varying contact areas, in accordance with an embodiment of the present disclosure.

In FIG. 10A, an experiment was conducted to validate the simulation using subject 1. The experiment aimed to confirm that series resonance is preferable to parallel resonance for RX 104 and to demonstrate the impact of Z_{contact}. A ground-connected signal generator 1004 served as the TX 102, coupling a 5 Vpk, 1 MHz sine wave onto the body 106. A ground-floated RX setup was also used, with an inductor configured for series or parallel resonance and a portable oscilloscope measuring the received voltage across the resistor. For series resonance, a 1 mH inductor was used with three different contact areas: 1 cm×1 cm, 5 cm×5 cm, and 10 cm×10 cm. For parallel resonance, a 220 uH inductor with a 10 cm×10 cm contact area was used. The results show that series resonance achieves significantly greater Pᵣₓ than parallel resonance, and a larger contact area further enhances Pᵣₓ. This finding indicates that for capacitive EQSHBP, RX 104 benefits more from a series resonance configuration than from parallel resonance, and a larger contact area minimizes Z_{contact} for improved Pᵣₓ. Additionally, due to non-idealities associated with the inductor, the observed improvement ratio between series and parallel resonance exceeds that in the simulation.

FIG. 10B is an experimental setup and analysis of TX series versus parallel resonance, highlighting that neither technique will change the ratio of V_{body}/V_{Cpp}, in accordance with an embodiment of the present disclosure.

In FIG. 10B, an experiment was conducted to validate the simulation from using subject 1. This experiment aimed to confirm that, for capacitive EQSHBP TX, neither series nor parallel resonance techniques may cancel the effect of Cᵣₑₜ and thus cannot alter the ratio between V_{C}_{ₚₚ} and V_{body}. An FPGA served as the ground-floated TX, coupling a 5 Vpk, 1 MHz square wave onto the body 106, with an inductor used for series or parallel resonance. A portable oscilloscope measured the voltage across the parasitic capacitor Cₚₚ, while a ground-connected oscilloscope 1002 measured the on-body voltage. The results demonstrate a consistent ratio between V_{C}_{ₚₚ} and V_{body} for both TX series and parallel resonance configurations, validating the conclusion that inductive resonance does not cancel the effect of Cᵣₑₜ for the TX 102.

In these experiments, the focus is to validate the biophysical modeling results and trends and not on maximizing the absolute Pᵣₓ or exact number matching between simulation and experiment. With more optimization from the device form factor and location, it is possible to achieve mW level power. To increase the Pᵣₓ, an inductor with a higher quality factor may be used for example, a generic commonly found in electronics laboratory inductor may be used.

FIG. 11 is a process flow diagram depicting an exemplary powering method 1100 for series resonant capacitive Electro-Quasi Static Human Body Powering (EQS-HBP) using a Human Body Communication (HBC) network, in accordance with an embodiment of the present disclosure. At step 1102, the method 1100 includes generating, by a transmitter 102, Electro-Quasi static (EQS) signals for powering a receiver 104. At step 1104, the method 1100 includes coupling, by the transmitter 102, the EQS signals to a conducting medium 106 for transmitting the EQS signals, using an Electro-Quasistatic Human Body Powering. The transmitter 102 electrically connects to the conducting medium 106, and the conducting medium 106 transfers the EQS signals from the transmitter 102 to the receiver 104. At step 1106, the method 1100 includes receiving, by the receiver 104, the EQS signals from the transmitter 102 through the conducting medium 106. At step 1108, the method 1100 includes delivering, by the receiver 104, power to an electrical load 116 associated with the receiver 104, using the received EQS signals. At step 1110, the method 1100 includes boosting, by one or more inductors 110, voltage of the EQS signals coupled to the conducting medium 106 at a series resonant frequency value, based on a quality factor value associated with the one or more inductors 110. At step 1112, the method 1100 includes boosting, by the one or more inductors 110, the power level of the EQS signals received at the receiver 104.

The present invention introduces an advanced method for capacitive electro-quasistatic (EQS) human body powering (HBP) to enable battery-less on-body devices. This advanced method is distinguished by its ability to significantly boost power transfer through the introduction of an inductor that facilitates a resonance effect. Traditional energy harvesting and wireless powering methods, such as piezoelectric, solar, radio frequency (RF), and ultrasound, face inherent limitations. These include low energy density, irregular availability, short effective range, and significant attenuation due to human body tissue. Such limitations hinder the reliable, prolonged operation of on-body devices. By leveraging the electro-quasistatic field, operating below 30 MHz, the present capacitive EQS-HBP method overcomes these challenges, enabling efficient power transfer while minimizing magnetic field variations and simplifying system design. Furthermore, a method to optimize the received power with the introduced resonance is also introduced.

This present invention introduces a method for capacitive electro-quasistatic (EQS) human body powering (HBP) to enable battery-less on-body devices. Traditional energy harvesting and wireless powering methods, such as piezoelectric, solar, radio frequency (RF), and ultrasound, face limitations in energy density, availability, and range. Capacitive EQS-HBP leverages the electro-quasistatic field, operating below 30 MHz, to minimize magnetic field variations, simplify system design, and enhance power transfer efficiency. The present series resonant technique of the present disclosure overcomes challenges posed by return path capacitance (Cᵣₑₜ), significantly boosting power received. This innovation may be applied in various scenarios of capacitive EQS-HBP to boost power received.

The present invention provides a method to enhance the power delivery in electro-quasistatic human body powering (EQS-HBP) system using inductor capacitor resonance technique. The present method may be applicable to devices connected to the body such as for example, but not limited to, wearable devices, holdable devices, touchable devices and the like. For example, a price tag display in the supermarket. The system includes a transmitter (TX) 102, a receiver (RX) 104 and a human body channel 106 and one or more inductors 110. The use of the one or more inductors 110 are either in the Tx 102 or RX 104 or both. At the RX, the power received is boosted through adding an inductor 110 in series with the electrical load 116 (series resonance). For example, a wearable battery charging system. The series resonance is between the inductor 110 and some capacitor. For example, one capacitor may be Cₚₚ. Cₚₚ 414 exists between the signal plate and the ground plate of the RX 104. The other capacitor may be the return path parasitic capacitor (Cᵣₑₜ). Any additional capacitor that is in parallel with Cₚₚ may also be used.

Given low to medium impedance (with reference to the AC impedance of Cᵣₑₜ), series resonance boosts voltage received by the electrical load 116. Series resonance boosts the voltage received through cancellation of the effect of Cᵣₑₜ. The effect of Cret is a high AC impedance in series with the electrical load that reduces the power received by the electrical load.

At the TX 102, the power transmitted is boosted through adding an inductor 110 in series with the TX 102 (series resonance). The series resonance is between the inductor 110 and some capacitor. In an example embodiment, one capacitor is Cₚₚ. Cₚₚ exists between the signal plate and the ground plate of the TX 102. Any additional capacitor that is in parallel with Cpp may be used. This series resonance boosts the voltage coupled onto the body 106 to boost power transmitted.

Further, the quality factor of the inductor 110 may substantially optimize the power delivered to the load 116 in which a higher inductor quality factor may result in greater power delivered to the load 116. The technique is applicable to the EQS frequency range which is less than 30 MHz.

At the TX 102, the power transmitted may benefit from a lower source impedance. The lower source impedance reduces loading effect and couples more voltage onto the body 106. The power transmitted may benefit from a higher Cᵣₑₜ. The higher Cᵣₑₜ may reduce the capacitive division between Cᵣₑₜ and the parasitic capacitor between body and the environmental ground (Cbody). Thus, more voltage may be coupled onto the body 106. This benefit is influenced by TX 102 device design. For example, a larger TX device would result in a larger Cᵣₑₜ 422 and thus higher benefit.

At the RX 104, the power transmitted may benefit from a lower Cₚₚ to Cᵣₑₜ ratio. The lower Cₚₚ to Cᵣₑₜ ratio may boost the voltage 418 received by the electrical load 116. Further, the power transmitted may benefit from a higher Cᵣₑₜ 420 magnitude. A higher Cᵣₑₜ 420 magnitude reduces the AC impedance of Cᵣₑₜ and thus gains more benefit from the effect of resonance cancellation.

At the TX 102 and the RX 104, the power delivered to the load would benefit from resonance alignment in which the TX frequency aligns with the TX series resonance frequency and the TX frequency aligns with the RX series resonance frequency.

At the TX 102, the power transmitted efficiency may be improved through the use of parallel resonance in which the inductor is in parallel with the TX signal source 108. Alternatively, the inductor resonates with the Cₚₚ (parallel resonance). The parallel resonance reduces the current through Cₚₚ. If series resonance and parallel resonance frequency aligns, the voltage coupled onto the body is unaffected by the parallel resonance while less power is wasted across the Cₚₚ, thus increasing the power transmitted efficacy.

The series resonance technique optimizes TX 102 and RX 104 configuration which the ground electrode is floating. For example, it is not connected to the environmental ground. The inverse of that may be that the ground electrode is connected to the environmental ground.

Furthermore, the optimal loading impedance after implementing series resonance is approximated as the inductor impedance when the inductor has a very low Q factor. Dependent on achieving perfect resonance when the Q factor is high, where if perfect resonance is achieved, the optimal loading impedance is approximated as R_{body}+Z_{contact}. If perfect resonance is not achieved, the optimal loading impedance is approximated using an equation that accounts for the residual return path impedance, the equation is shown below with k₂-k₅ found earlier:

$${R}_{load opt}^{2} \approx \frac{{k}_{3} {k}_{5} - 3 {k}_{2} {k}_{4} - \sqrt{{( 3 {k}_{2} {k}_{4} - {k}_{3} {k}_{5} )}^{2} - 4 {k}_{2} {k}_{3} {k}_{4} {k}_{5}}}{2 {k}_{2} {k}_{5}} \qquad equation ( 26 )$$

What has been described and illustrated herein are examples of the present disclosure. The terms, descriptions, and figures used herein are set forth by way of illustration only and are not meant as limitations. Many variations are possible within the spirit and scope of the subject matter, which is intended to be defined by the following claims and their equivalents in which all terms are meant in their broadest reasonable sense unless otherwise indicated.

The written description describes the subject matter herein to enable any person skilled in the art to make and use the embodiments. The scope of the subject matter embodiments is defined by the claims and may include other modifications that occur to those skilled in the art. Such other modifications are intended to be within the scope of the claims if they have similar elements that do not differ from the literal language of the claims or if they include equivalent elements with insubstantial differences from the literal language of the claims.

The embodiments herein may comprise hardware and software elements. The embodiments that are implemented in software include but are not limited to, firmware, resident software, microcode, a. The functions performed by various modules described herein may be implemented in other modules or combinations of other modules. For the purposes of this description, a computer-usable or computer-readable medium may be any apparatus that may comprise, store, communicate, propagate, or transport the program for use by or in connection with the instruction execution system, apparatus, or device.

A description of an embodiment with several components in communication with each other does not imply that all such components are required. On the contrary, a variety of optional components are described to illustrate the wide variety of possible embodiments of the invention. When a single device or article is described herein, it will be apparent that more than one device/article (whether or not they cooperate) may be used in place of a single device/article. Similarly, where more than one device or article is described herein (whether or not they cooperate), it will be apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments of the invention need not include the device itself.

The illustrated steps are set out to explain the exemplary embodiments shown, and it should be anticipated that ongoing technological development will change the manner in which particular functions are performed. These examples are presented herein for purposes of illustration, and not limitation. Further, the boundaries of the functional building blocks have been arbitrarily defined herein for the convenience of the description. Alternative boundaries may be defined so long as the specified functions and relationships thereof are appropriately performed. Alternatives (including equivalents, extensions, variations, deviations, and the like, of those described herein) will be apparent to persons skilled in the relevant art(s) based on the teachings contained herein. Such alternatives fall within the scope and spirit of the disclosed embodiments. Also, the words “comprising,” “having,” “containing,” and “including,” and other similar forms are intended to be equivalent in meaning and be open-ended in that an item or items following any one of these words is not meant to be an exhaustive listing of such item or items or meant to be limited to only the listed item or items. It must also be noted that as used herein and in the appended claims, the singular forms “a”, “an”, and “the” include plural references unless the context clearly dictates otherwise.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based here on. Accordingly, the embodiments of the present invention are intended to be illustrative, but not limited, of the scope of the invention, which is outlined in the following claims.

### APPENDIX I Derivation for Zᵢₙ, P_{R}_{_{load}} and R_{load}

$${Z}_{i n} = ( \frac{1}{\frac{1}{{Z}_{{C}_{pp}}} + \frac{1}{{Z}_{L} + {R}_{load}}} ) + {Z}_{{C}_{ret}} \qquad equation ( 27 )$$

$${Z}_{in} = \frac{{Z}_{{C}_{pp}} * ( {Z}_{L} + {R}_{load} )}{{Z}_{{C}_{pp}} + {Z}_{L} + {R}_{load}} + {Z}_{{C}_{ret}} \qquad equation ( 28 )$$

$${Z}_{in} = \frac{{Z}_{{C}_{pp}} ( {Z}_{L} + {R}_{load} ) + {Z}_{{C}_{ret}} ( {Z}_{{C}_{pp}} + {Z}_{L} + {R}_{load} )}{{Z}_{{C}_{pp}} + {Z}_{L} + {R}_{load}} \qquad equation ( 29 )$$

$${Z}_{in} = \frac{{Z}_{L} + {R}_{load} + \frac{{Z}_{{C}_{res}}}{{Z}_{{C}_{pp}}} ( {Z}_{{C}_{pp}} + {Z}_{L} + {R}_{load} )}{1 + \frac{1}{{Z}_{{C}_{pp}}} ( {Z}_{L} + {R}_{load} )} \qquad equation ( 30 )$$

$${Z}_{in} = \frac{{Z}_{L} + {R}_{load} + {Z}_{{C}_{ret}} + \frac{{Z}_{{C}_{ret}}}{{Z}_{{C}_{pp}}} ( {Z}_{L} + {R}_{load} )}{1 + \frac{1}{{Z}_{{C}_{pp}}} ( {Z}_{L} + {R}_{load} )} \qquad equation ( 31 )$$

$${Z}_{in} = \frac{{Z}_{L} + {R}_{load} + \frac{1}{{SC}_{ett}} + \frac{{C}_{pp}}{{C}_{ret}} ( {Z}_{L} + {R}_{load} )}{1 + {SC}_{pp} ( {Z}_{L} + {R}_{load} )} \qquad equation ( 32 )$$

$${Z}_{in} = \frac{\frac{1}{{SC}_{ret}} + ( 1 + \frac{{C}_{pp}}{{C}_{ret}} ) ( {Z}_{L} + {R}_{load} )}{1 + {SC}_{pp} ( {Z}_{L} + {R}_{load} )} \qquad equation ( 33 )$$

$${Z}_{in} = \frac{\frac{1}{{SC}_{ret}^{*}} + ( \frac{{C}_{ret} + {C}_{pp}}{{C}_{ret}} ) ( {Z}_{L} + {R}_{load} )}{1 + {SC}_{pp} ( {Z}_{L} + {R}_{load} )} \qquad equation ( 34 )$$

$${Z}_{in} = \frac{\frac{1}{{SC}_{ret}} + ( \frac{{C}_{ret} + {C}_{pp}}{{C}_{ret}} ) ( SL + {R}_{load} )}{1 + {SC}_{pp} ( SL + {R}_{load} )} \qquad equation ( 35 )$$

$${Z}_{in} = \frac{1 + S ( {C}_{ret} + {C}_{pp} ) ( SL + {R}_{load} )}{{SC}_{ret} + {S}^{2} {C}_{pp} {C}_{ret} ( SL + {R}_{load} )} \qquad equation ( 36 )$$

$${Z}_{in} = \frac{1 + ( {C}_{ret} + {C}_{pp} ) {S}^{2} L + S ( {C}_{ret} + {C}_{pp} ) {R}_{load}}{{SC}_{ret} + {S}^{3} {C}_{pp} {C}_{ret} L + {S}^{2} {C}_{pp} {C}_{ret} {R}_{load}} \qquad equation ( 37 )$$

$${Z}_{in} = \frac{1 - ( {C}_{ret} + {C}_{pp} ) L {ω}^{2} + j ( {C}_{ret} + {C}_{pp} ) {R}_{load} ω}{j ω {C}_{ret} - j {ω}^{3} {C}_{pp} {C}_{ret} L - {ω}^{2} {C}_{pp} {C}_{ret} {R}_{load}} \qquad equation ( 38 )$$

$${Z}_{in} = \frac{1 - ( {C}_{ret} + {C}_{pp} ) L {ω}^{2} + j ( {C}_{ret} + {C}_{pp} ) {R}_{load} ω}{- {ω}^{2} {C}_{pp} {C}_{ret} {R}_{load} + j ( ω {C}_{ret} - {ω}^{3} {C}_{pp} {C}_{ret} L )} \qquad equation ( 39 )$$

$$\vert {Z}_{in} \vert = \frac{\sqrt{{[ 1 - ( {C}_{ret} + {C}_{pp} ) L {ω}^{2} ]}^{2} + {[ ( {C}_{ret} + {C}_{pp} ) {R}_{load} ω ]}^{2}}}{\sqrt{{( {ω}^{2} {C}_{pp} {C}_{ret} {R}_{load} )}^{2} + {( ω {C}_{ret} - {ω}^{3} {C}_{pp} {C}_{ret} L )}^{2}}} \qquad equation ( 40 )$$

$$\vert {Z}_{in} \vert = \frac{\sqrt{{[ 1 - ( {C}_{ret} + {C}_{pp} ) L {ω}^{2} ]}^{2} + {[ ( {C}_{ret} + {C}_{pp} ) ω ]}^{2} {R}_{load}^{2}}}{\sqrt{{( {ω}^{2} {C}_{pp} {C}_{ret} )}^{2} {R}_{load}^{2} + {( ω {C}_{ret} - {ω}^{3} {C}_{pp} {C}_{ret} L )}^{2}}} \qquad equation ( 41 )$$

To simplify:

$${k}_{2} = {( {ω}^{2} {C}_{pp} {C}_{ref} )}^{2} \qquad equation ( 42 )$$

$${k}_{3} = {( ω {C}_{ret} - {ω}^{3} {C}_{pp} {C}_{ref} L )}^{2} \qquad equation ( 43 )$$

$${k}_{4} = {[ 1 - ( {C}_{ret} + {C}_{pp} ) L {ω}^{2} ]}^{2} \qquad equation ( 44 )$$

$${k}_{5} = {[ ( {C}_{ret} + {C}_{p p} ) ω ]}^{2} \qquad equation ( 45 )$$

### Thus:

$$\vert {Z}_{in} \vert = \sqrt{\frac{{k}_{4} + {k}_{5} {R}_{load}^{2}}{{k}_{2} {R}_{load}^{2} + {k}_{3}}} \qquad equation ( 46 )$$

$${P}_{{R}_{load}} = {( \frac{{C}_{pp} + {C}_{ret}}{{C}_{ret}} \frac{{V}_{body}}{{Z}_{in}} )}^{2} {R}_{load} \qquad equation ( 47 )$$

$${P}_{{R}_{load}} = {( \frac{{C}_{pp} + {C}_{ret}}{{C}_{ret}} * {V}_{body} )}^{2} * \frac{{k}_{2} {R}_{load}^{2} + {k}_{3}}{{k}_{4} + {k}_{5} {R}_{load}^{2}} * {R}_{load} \qquad equation ( 48 )$$

To simplify:

$${k}_{1} = {( \frac{{c}_{pp} + {c}_{ret}}{{C}_{ret}} * {V}_{body} )}^{2} \qquad equation ( 49 )$$

$${P}_{{R}_{load}} = {k}_{1} * \frac{{k}_{2} {R}_{load}^{2} + {k}_{3}}{{k}_{4} + {k}_{5} {R}_{load}^{2}} * {R}_{load}$$

To find local maxima where power is maximized with respect to R_{load}:

$$\frac{d {P}_{{R}_{load}}}{d {R}_{load}} = \frac{1}{d {R}_{load}} ( {k}_{1} * \frac{{k}_{2} {R}_{load}^{2} + {k}_{3}}{{k}_{4} + {k}_{5} {R}_{load}^{2}} * {R}_{load} ) = 0 \qquad equation ( 50 )$$

$$\frac{1}{d {R}_{load}} ( {k}_{1} ( \frac{{k}_{2} {R}_{load}^{3} + {k}_{3} {R}_{load}}{{k}_{4} + {k}_{5} {R}_{load}^{2}} ) ) = \frac{{k}_{I}}{{( {k}_{4} + {k}_{5} {R}_{load}^{2} )}^{2}} [ ( {k}_{4} + {k}_{5} {R}_{load}^{2} ) ( 3 {k}_{2} {R}_{load}^{2} + {k}_{3} ) - ( {k}_{2} {R}_{load}^{3} + {k}_{3} {R}_{load} ) ( 2 {k}_{5} {R}_{load} ) ] \qquad equation ( 51 )$$

### Thus,

$$( {k}_{4} + {k}_{5} {R}_{load}^{2} ) ( 3 {k}_{2} {R}_{load}^{2} + {k}_{3} ) - ( {k}_{2} {R}_{load}^{3} + {k}_{3} {R}_{load} ) ( 2 {k}_{5} {R}_{load} ) = {R}_{load}^{4} ( {k}_{2} {k}_{5} ) + {R}_{load}^{2} ( 3 {k}_{2} {k}_{4} - {k}_{3} {k}_{5} ) + {k}_{3} {k}_{4} = 0$$

$${R}_{load}^{2} = \frac{- ( 3 {k}_{2} {k}_{4} - {k}_{3} {k}_{5} \pm \sqrt{{( 3 {k}_{2} {k}_{4} - {k}_{3} {k}_{5} )}^{2} - 4 * {k}_{2} {k}_{3} {k}_{4} {k}_{5}}}{2 * {k}_{2} {k}_{5}} = \frac{{k}_{3} {k}_{5} - 3 {k}_{2} {k}_{4} - \sqrt{{( 3 {k}_{2} {k}_{4} - {k}_{3} {k}_{5} )}^{2} - 4 {k}_{2} {k}_{3} {k}_{4} {k}_{5}}}{2 {k}_{2} {k}_{5}} \qquad equation ( 52 )$$

1. A powering system for series resonant capacitive Electro-Quasi Static Human Body Powering (EQS-HBP) using a Human Body Powering (HBP) network comprising:
a transmitter configured to:
generate Electro-Quasi static (EQS) signals for powering a receiver;
couple the EQS signals to a conducting medium for transmitting the EQS signals, using an Electro-Quasistatic Human Body Powering, wherein the transmitter electrically connects to the conducting medium, and wherein the conducting medium transfers the EQS signals from the transmitter to the receiver;
the receiver electrically attached to the conducting medium, wherein the receiver is configured to:
receive the EQS signals from the transmitter through the conducting medium; and
deliver power to an electrical load associated with the receiver, using the received EQS signals; and
determine an optimal loading resistance, wherein the receiver is configured to:
set the optimal loading resistance value based on a body resistance and the contact impedance if the TX transmitting frequency is aligned with the TX series resonance frequency and aligned with the RX resonance frequency and the quality factor of the inductor is high;
set the optimal loading resistance value based on an Equivalent Series Resistance (ESR) if the TX transmitting frequency is aligned with the TX series resonance frequency and aligned with the RX resonance frequency and the inductor quality factor is low;
set the optimal loading resistance value based on a residual capacitive reactance if the TX transmitting frequency fails to align with the TX series resonance frequency and with the RX resonance frequency and the inductor quality factor is high; and
set the optimal loading resistance value based on the Equivalent Series Resistance (ESR) of the inductor if the TX transmitting frequency fails to align with the TX series resonance frequency and with the RX resonance frequency and the inductor quality factor is low,
one or more inductors electrically coupled to at least one of the transmitter and the receiver, wherein the one or more inductors are configured to:
boost voltage of the EQS signals coupled to the conducting medium at a series resonant frequency value, based on a quality factor value associated with the one or more inductors; and
boost power level of the EQS signals received at the receiver.

2. The powering system of claim 1, wherein to deliver the power to the electrical load associated with the receiver, using the received EQS signals, the receiver comprises:
a signal electrode electrically connected to the conducting medium, wherein the signal electrode is configured to:
receive the EQS signals from the transmitter, through the medium, wherein the received EQS signals corresponds to a primary voltage value induced by the EQS signals transmitted from the transmitter; and
a ground electrode coupled to a ground terminal, wherein the ground electrode is configured to receive a secondary voltage value induced by the EQS signals transmitted from the transmitter, wherein the receiver is configured to:
receive a differential voltage value between the signal electrode, and the ground electrode of the receiver, based on the primary voltage value and the secondary voltage value; and
deliver power to the electrical load associated with the receiver, based on the received differential voltage value.

3. The powering system of claim 2, wherein the receiver is configured to receive a differential alternating current voltage across the received EQS signal and the ground electrode, wherein differential alternating current voltage corresponds to a frequency of the electro-quasistatic signals with a reduced amplitude, wherein the amplitude is reduced based on the transmitter and receiver ground configurations.

4. The powering system of claim 1, wherein the series resonant frequency value of the transmitter depends on size of the one or more inductors with respect to size of a primary parasitic capacitor connected parallelly to the transmitter.

5. The powering system of claim 1, wherein to boost the voltage of the EQS signals coupled to the conducting medium at the series resonant frequency value, based on the quality factor value associated with the one or more inductors, the one or more inductors are configured to:
boost the voltage of the EQS signals coupled to the conducting medium with a pre-defined gain, wherein the pre-defined gain is determined by a combination of the quality factor value of the one or more inductors connected in series to the transmitter and an additional resistor value added to adjust an overall gain of a circuit connected in series to the one or more inductors.

6. The powering system of claim 1, wherein the transmitter is coupled to a ground terminal with a primary capacitive coupling, wherein the primary capacitive coupling corresponds to a primary return path parasitic capacitor connected between a ground electrode of the transmitter, and the ground terminal.

7. The powering system of claim 1, wherein the receiver is coupled to a ground terminal with a secondary capacitive coupling, wherein the secondary capacitive coupling corresponds to a secondary return path parasitic capacitor connected between a ground electrode of the receiver, and the ground terminal.

8. The powering system of claim 1, wherein the transmitter is configured to transfer the EQS signals at a frequency of less than 30 MHz.

9. (canceled)

10. The powering system of claim 1, wherein the series resonant frequency value of the transmitter is configured to be aligned with the series resonant frequency value of the receiver to boost the power level of the EQS signals received at the receiver.

11. The powering system of claim 1, wherein to boost power level of the EQS signals received, the receiver, in a ground-floated configuration, comprises:
an inductor in series with the electrical load; and
a series resonance between the inductor and at least one capacitor, wherein the at least one capacitor comprises one of:
a parasitic capacitor Cₚₚ existing between a signal electrode and a ground electrode of the receiver;
a return path parasitic capacitor (Cᵣₑₜ); and
one or more additional capacitor in parallel with the parasitic capacitor Cₚₚ to adjust the resonant frequency;
wherein the series resonance boosts a voltage received by the electrical load; and
wherein the series resonance boosts the voltage received through cancellation of effect of the return path parasitic capacitor Cᵣₑₜ.

12. The powering system of claim 1, wherein the transmitter, in a ground floated configuration, comprises:
an inductor in series with a transmitting source;
a series resonance between the inductor and at least one capacitor, wherein the at least one capacitor comprises one of:
a parasitic capacitor Cₚₚ existing between a signal electrode and a ground electrode of the transmitter; and
an additional capacitor in parallel with the parasitic capacitor Cₚₚ, and
wherein the series resonance boosts the voltage coupled onto the conducting medium to boost the power transmitted.

13. The powering system of claim 1, wherein at the receiver, when the receiver is in ground-floated configuration, with inductor series resonance, the power received depends on a ratio of parasitic capacitor Cₚₚ to return path parasitic capacitor Cᵣₑₜ value, and on a specific magnitude value of the return path parasitic capacitor Cᵣₑₜ.

14. The powering system of claim 1, wherein at the transmitter and the receiver, in a series resonance configuration, when the transmitter and the receiver are in ground-floated configuration, the power delivered to the load depends on a resonance alignment where a transmitter (Tx) frequency aligns with a transmitter (TX) series resonance frequency and where the transmitter TX frequency aligns with a receiver RX series resonance frequency.

15. The powering system of claim 1, wherein at the transmitter, when the transmitter is in ground-floated configuration, the power transmitted depends on a parallel resonance, where an inductor is connected in parallel with a transmitter signal source, wherein the inductor resonates with a Cₚₚ to induce parallel resonance.

16. The powering system of claim 1, wherein the receiver is configured to:
determine if the receiver is ground connected to determine if a series resonance is required; and
match an impendence to the Body impedance value and a contact impedance if the receiver is ground connected.

17. The powering system of claim 1, wherein the receiver is configured to:
determine if the receiver is ground floated and the series resonance is required;
determine if the Quality (Q) factor corresponds to one of a primary value and a secondary value if the receiver is ground-floated and the series resonance is determined to be required;
determine if an impedance is required to be matched to the receiver when the Q factor corresponds to the secondary value;
determine if a TX transmitting frequency is aligned with a TX series resonance frequency and aligned with a RX resonance frequency; and
determine an optimal loading resistance based on interactions between reactive components of an inductor and capacitive elements of capacitors.

18. (canceled)

19. The powering system of claim 1, wherein at the receiver, in the ground-floated configuration, the one or more inductors are configured to be connected in series with the load to boost the power level of the EQS signals received at the receiver.

20. The powering system of claim 1, wherein at the transmitter, the one or more inductors are configured to be connected in series with a transmitting source to boost the voltage of the EQS signals coupled to the conducting medium, wherein to boost the voltage of the EQS signals, the transmitter is configured to:
determine if the transmitter is one of ground-connected and ground-floated;
determine if series resonance is required to be used and determine a gain value to be used;
set the gain value to a lower range if the transmitter is ground-connected and the series resonance us required to be used; and
boost the voltage transmitted if the transmitter is ground-floated, using the series resonance.

21. The powering system of claim 1, further comprising:
a primary parasitic capacitor Cₚₚ connected between a signal electrode, and a ground electrode of the transmitter; and
a primary return path parasitic capacitor Cᵣₑₜ connected between the ground electrode of the transmitter, and a ground terminal, wherein the series resonant frequency value of the transmitter is configured to exist between the one or more inductors, and at least one of the primary parasitic capacitor, and the primary return path parasitic capacitor, and wherein the series resonant frequency value of the transmitter boosts the voltage of the EQS signals coupled to the conducting medium.

22. The powering system of claim 1, further comprising:
a secondary parasitic capacitor connected between a signal electrode, and a ground electrode of the receiver; and
a secondary return path parasitic capacitor Cᵣₑₜ connected between the ground electrode of the receiver, and a ground terminal, wherein the series resonant frequency value of the receiver is configured to exist between the one or more inductors, and at least one of the secondary parasitic capacitor, and the secondary return path parasitic capacitor, and wherein the series resonant frequency value of the receiver adjusts an impedance value of the secondary return path capacitor, to boost the power level of the EQS signals received at the receiver.

23. The powering system of claim 1, wherein the quality factor value of the one or more inductors is directly proportional to amount of the power delivered to the receiver.

24. The powering system of claim 1, wherein at the transmitter, the boosted voltage of the EQS signals coupled to the conducting medium depends on one or more secondary inductors connected in parallel with the transmitter, wherein the one or more secondary inductors are configured to operate at a parallel resonant frequency value, wherein the parallel resonant frequency value adjusts a current value through the primary parasitic capacitor, and wherein the series resonant frequency value and the parallel resonant frequency value is configured to align to boost the voltage of the EQS signals coupled to the conducting medium.

25. A powering method for series resonant capacitive Electro-Quasi Static Human Body Powering (EQS-HBP) using a Human Body Communication (HBC) network comprising:
generating, by a transmitter, Electro-Quasi static (EQS) signals for powering a receiver;
coupling, by the transmitter, the EQS signals to a conducting medium for transmitting the EQS signals, using an Electro-Quasistatic Human Body Powering, wherein the transmitter electrically connects to the conducting medium, and wherein the conducting medium transfers the EQS signals from the transmitter to the receiver;
receiving, by the receiver, the EQS signals from the transmitter through the conducting medium;
delivering, by the receiver, power to an electrical load associated with the receiver, using the received EQS signals;
boosting, by one or more inductors, voltage of the EQS signals coupled to the conducting medium at a series resonant frequency value, based on a quality factor value associated with the one or more inductors;
boosting, by the one or more inductors, the power level of the EQS signals received at the receiver;
setting, by the receiver, the optimal loading resistance value based on a body resistance and the contact impedance if the TX transmitting frequency is aligned with the TX series resonance frequency and aligned with the RX resonance frequency and the quality factor of the inductor is high;
setting, by the receiver, the optimal loading resistance value based on an Equivalent Series Resistance (ESR) if the TX transmitting frequency is aligned with the TX series resonance frequency and aligned with the RX resonance frequency and the inductor quality factor is low;
setting, by the receiver, the optimal loading resistance value based on a residual capacitive reactance if the TX transmitting frequency fails to align with the TX series resonance frequency and with the RX resonance frequency and the inductor quality factor is high; and
setting, by the receiver, the optimal loading resistance value based on the Equivalent Series Resistance (ESR) of the inductor if the TX transmitting frequency fails to align with the TX series resonance frequency and with the RX resonance frequency and the inductor quality factor is low.
